(19) United States
(12) Patent Application Publication
(10) Pub. No.: US 2026/0005693 A1
(43) Pub. Date: Jan. 1, 2026

(54) SEMICONDUCTOR DEVICE

(71) Applicant: ROHM CO., LTD., Kyoto-shi (JP)

(72) Inventor: Junichi SEKITO, Kyoto-shi (JP)

(21) Appl. No.: 19/318,927

(22) Filed: Sep. 4, 2025

Related U.S. Application Data
(63) Continuation of application No. PCT/JP2024/006251, filed on Feb. 21, 2024.

(30) Foreign Application Priority Data
Mar. 9, 2023 (JP) 2023-036142

(51) Int. Cl. H03K 19/0175; H01L 23/495; H01L 25/065; H03K 19/20; H04L 25/02

(52) U.S. Cl. CPC H03K 19/01759; H01L 23/49555; H01L 25/0655; H04L 25/0266; H03K 19/20

(57) ABSTRACT

A semiconductor device includes a first chip and a second chip. Each chip includes a high-side pad that receives a high-side voltage, a low-side pad that receives a low-side voltage, two or more control pads, an input pad, an output pad, and a functional circuit. In each chip, the two or more control pads are each pulled down to the low-side voltage or pulled up to the high-side voltage. In each chip, the two or more control pads include a target control pad that receives an external control signal. In each chip, an internal control signal is generated on the basis of two or more signals applied to the two or more control pads, and an operation of the functional circuit is controlled on the basis of the internal control signal.

### CROSS REFERENCE TO RELATED APPLICATIONS

This application is a continuation under 35 U.S.C. § 120 of PCT/JP2024/006251 filed on Feb. 21, 2024, which is incorporated herein by reference, and which claimed priority Japanese Patent Application No. 2023-036142 filed on Mar. 9, 2023. The present application likewise claims priority under 35 U.S.C. § 119 to Japanese Application No. 2023-036142, filed Mar. 9, 2023, the entire content of which is also incorporated herein by reference.

### TECHNICAL FIELD

The present disclosure relates to a semiconductor device.

### BACKGROUND ART

A plurality of semiconductor chips having the same function or corresponding functions may be disposed in a semiconductor device. The plurality of semiconductor chips can constitute a digital isolator, for example.

### LIST OF CITATIONS

### Patent Literature

Patent Document 1: JP-A-2019-140641

### BRIEF DESCRIPTION OF DRAWINGS

FIG. 1 is an overall structural diagram of a system (signal transmission system) according to a first embodiment of the present disclosure.

FIG. 2 is an external perspective view of a semiconductor device according to the first embodiment of the present disclosure.

FIG. 3 is a diagram illustrating a chip configuration of the semiconductor device according to the first embodiment of the present disclosure.

FIG. 4 is a diagram illustrating a relationship among the semiconductor device, an X-axis, a Y-axis and a Z-axis, according to the first embodiment of the present disclosure.

FIG. 5 is a relationship diagram among two chips, an external terminal group, and a pad group, according to a reference example.

FIG. 6 is a schematic diagram illustrating a relationship between a first chip and a second chip when commonalization of the chips is performed, according to the first embodiment of the present disclosure.

FIG. 7 is a configuration diagram of the semiconductor device according to Example EX1_1 of the first embodiment of the present disclosure.

FIG. 8 is a configuration diagram of one chip according to the Example EX1_1 of the first embodiment of the present disclosure.

FIG. 9 is a configuration diagram of the two chips according to Example EX1_1 of the first embodiment of the present disclosure.

FIG. 10 is a diagram for describing an arrangement positional relationship of the two chips, according to Example EX1_1 of the first embodiment of the present disclosure.

FIG. 11 is a diagram illustrating a relationship among an external control signal, an internal control signal, and an operation of a functional circuit, according to Example EX1_1 of the first embodiment of the present disclosure.

FIG. 12 is a configuration diagram of a circuit that performs signal transmission in an insulated form, according to Example EX1_1 of the first embodiment of the present disclosure.

FIG. 13 is a configuration diagram of a circuit that performs signal transmission in an insulated form, according to Example EX1_1 of the first embodiment of the present disclosure.

FIG. 14 is a configuration diagram of the semiconductor device, according to Example EX1_2 of the first embodiment of the present disclosure.

FIG. 15 is a configuration diagram of the semiconductor device, according to Example EX1_3 of the first embodiment of the present disclosure.

FIG. 16 is a modified configuration diagram of the semiconductor device, according to Example EX1_3 of the first embodiment of the present disclosure.

FIG. 17 is a configuration diagram of the semiconductor device, according to Example EX1_4 of the first embodiment of the present disclosure.

FIG. 18 is a diagram illustrating a manner in which a lead and a pad are connected by wire bonding, according to Example EX1_5 of the first embodiment of the present disclosure.

FIG. 19 is a diagram illustrating a manner in which a lead and two pads are connected by wire bonding, according to Example EX1_5 of the first embodiment of the present disclosure.

FIG. 20 is a diagram illustrating a manner in which a lead and two pads are connected by wire bonding, according to Example EX1_5 of the first embodiment of the present disclosure.

FIG. 21 is an overall structural diagram of the system (signal transmission system), according to a second embodiment of the present disclosure.

### DESCRIPTION OF EMBODIMENTS

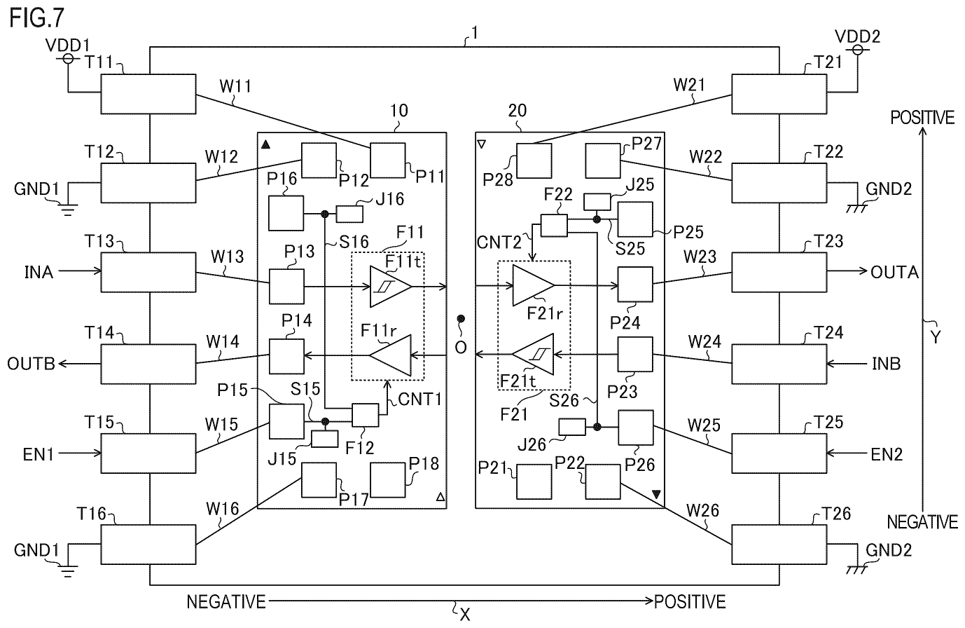

Hereinafter, an example of an embodiment of the present disclosure is specifically described with reference to the drawings. In the drawings to be referred to, the same part is denoted by the same sign, and overlapping description of the same part is omitted as a rule. Note that in this specification, for simple description, by writing a symbol or sign representing information, a signal, a physical amount, a functional unit, a circuit, an element or component, or the like, a name of the information, signal, physical amount, functional unit, circuit, element or component, or the like corresponding to the symbol or sign may be omitted or written in short. For instance, an internal control signal generation circuit (see FIG. 7) denoted by “F12” described later may be written as an internal control signal generation circuit F12, or may be written in short as a circuit F12, which indicate the same thing.

In the description of the embodiment of the present disclosure, a level means a potential level, and for an arbitrary noted signal or voltage, a high level has a higher potential than a low level. For an arbitrary noted signal or voltage, if the signal or the voltage is at high level, it strictly means that the level of the signal or the voltage is at high level, while if the signal or the voltage is at low level, it strictly means that the level of the signal or the voltage is at low level. It can be understood that a connection between a plurality of arbitrary parts forming a circuit, such as circuit elements, wires, and terminals, means an electric connection unless otherwise noted.

### First Embodiment

A first embodiment of the present disclosure is described. FIG. 1 illustrates an overall configuration of a system SYS that is a signal transmission system according to the first embodiment. The system SYS includes circuit blocks CB1 and CB2. In the system SYS, a processing device 2 and a voltage source VSI are disposed in the circuit block CB1, while a processing device 3 and a voltage source VS2 are disposed in the circuit block CB2. The circuit blocks CB1 and CB2 are electrically insulated from each other. In this specification, insulation means that transmission of DC signal and a DC power is disconnected. As to the circuit blocks CB1 and CB2, one of them may be referred to as a primary circuit, and the other may be referred to as a secondary circuit.

In the system SYS, a semiconductor device 1 is disposed over the circuit blocks CB1 and CB2. The semiconductor device 1 functions as a so-called digital isolator, and realizes bidirectional communication between the processing devices 2 and 3, while maintaining the insulation between the processing devices 2 and 3.

A ground in the circuit block CB1 is denoted by “GND1”, while a ground in the circuit block CB2 is denoted by “GND2”. An arbitrary voltage or signal in the circuit block CB1 is a voltage or signal with respect to the ground GND1, and has a potential with respect to the ground GND1. An arbitrary voltage or signal in the circuit block CB2 is a voltage or signal with respect to the ground GND2, and has a potential with respect to the ground GND2. In each of the circuit blocks CB1 and CB2, the ground indicates a reference conductive part having a reference potential of 0 V (zero volts), or indicates the reference potential itself. However, the ground GND1 and the ground GND2 are insulated from each other and hence can have different potentials. The reference conductive part is formed of a conductor such as metal.

In the circuit block CB1, the voltage source VSI generates and outputs a power supply voltage VDDI that is a positive DC voltage with respect to the potential of the ground GND1. The processing device 2 is connected to the ground GND1 and is supplied with the power supply voltage VDDI from the voltage source VS1. The processing device 2 is driven on the basis of the power supply voltage VDDI with respect to the potential of the ground GND1. However, the processing device 2 may be a device that is driven by a power supply voltage different from the power supply voltage VDD1. In the circuit block CB2, the voltage source VS2 generates and outputs a power supply voltage VDD2 that is a positive DC voltage with respect to the potential of the ground GND2. The processing device 3 is connected to the ground GND2 and is supplied with the power supply voltage VDD2 from the voltage source VS2. The processing device 3 is driven on the basis of the power supply voltage VDD2 with respect to the potential of the ground GND2. However, the processing device 3 may be a device that is driven by a power supply voltage different from the power supply voltage VDD2. Each of the processing devices 2 and 3 may be an arbitrary microprocessor, for example.

The semiconductor device 1 is connected to the grounds GND1 and GND2, and is supplied with the power supply voltages VDD1 and VDD2 from the voltage sources VS1 and VS2. In the circuit of the semiconductor device 1, the circuit belonging to the circuit block CB1 is driven on the basis of the power supply voltage VDD1 with respect to the potential of the ground GND1. In the circuit of the semiconductor device 1, the circuit belonging to the circuit block CB2 is driven on the basis of the power supply voltage VDD2 with respect to the potential of the ground GND2.

The processing device 2 outputs signals INA and EN1 to the semiconductor device 1. The processing device 3 outputs signals INB and EN2 to the semiconductor device 1. In the processing device 2, a device that outputs the signal INA and a device that outputs the signal EN1 may be disposed separately. In the processing device 3, a device that outputs the signal INB and a device that outputs the signal EN2 may be disposed separately. In an active state described later, the semiconductor device 1 outputs a signal OUTA based on the signal INA and outputs a signal OUTB based on the signal INB. The output signal OUTA of the semiconductor device 1 is supplied to the processing device 3, and the output signal OUTB of the semiconductor device 1 is supplied to the processing device 2. The signals INA, OUTB, EN1, OUTA, INB and EN2 are each a binary signal having high level or low level. However, as to the signals INA, OUTB and EN1 belonging to signals in the circuit block CB1, high level has the potential of the power supply voltage VDD1, while low level has the potential of the ground GND1 (omitting an error). As to the signals OUTA, INB and EN2 belonging to signals in the circuit block CB2, high level has a potential of the power supply voltage VDD2, while low level has the potential of the ground GND2 (omitting an error).

The signals EN1 and EN2 are enable signals. When the signals EN1 and EN2 are both in asserted state, the semiconductor device 1 realizes bidirectional communication between the processing devices 2 and 3. In other words, when the signals EN1 and EN2 are both in asserted state, the semiconductor device 1 performs a first transmission for transmitting the signal INA supplied from the processing device 2 as the signal OUTA to the processing device 3, and a second transmission for transmitting the signal INB supplied from the processing device 3 as the signal OUTB to the processing device 2. Here, it is supposed that the signals EN1 and EN2 having high level correspond to the asserted state, and that the signals EN1 and EN2 having low level correspond to a negated state. When the signal EN1 is in the negated state, the second transmission is not performed. When the signal EN2 is in negated state, the first transmission is not performed. Alternatively, when at least one of the signals EN1 and EN2 is in the negated state, both the first transmission and the second transmission are not performed.

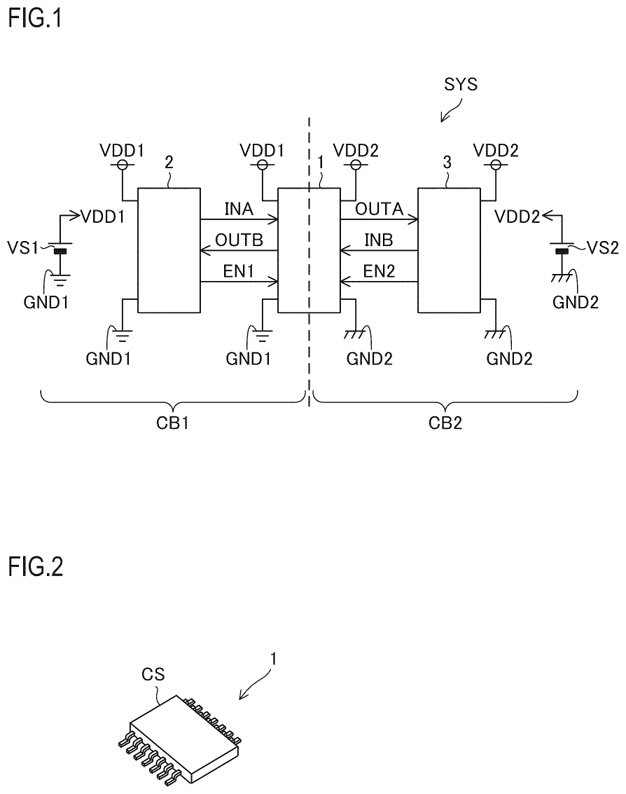

FIG. 2 is an external perspective view of the semiconductor device 1. The semiconductor device 1 is an electronic component including a semiconductor chip having a semiconductor integrated circuit formed on a semiconductor substrate, a case CS housing the semiconductor chip, and a plurality of external terminals exposed from the case CS to the outside of the semiconductor device 1. The semiconductor chip is sealed inside the case CS made of resin, and the semiconductor device 1 is formed. Note that in the semiconductor device 1 illustrated in FIG. 2, the number of the external terminals and shapes thereof, and a type of the case CS are merely an example, and they can be arbitrarily designed.

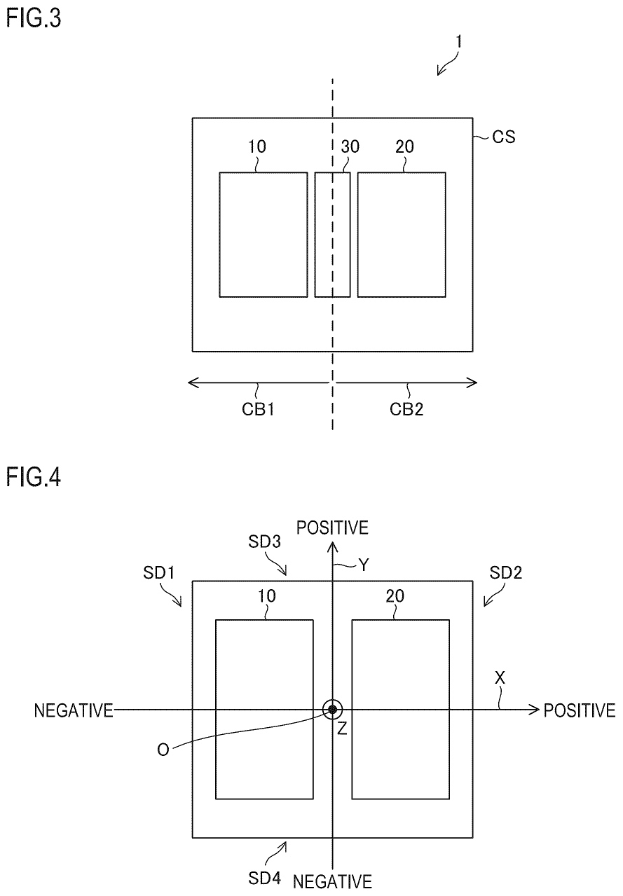

FIG. 3 illustrates a chip configuration diagram of the semiconductor device 1. The semiconductor device 1 has chips 10, 20 and 30 as three semiconductor chips. The chips 10, 20 and 30 are housed in the case CS. The chip 10 is disposed in the circuit block CB1, and hence circuits and wirings in the chip 10 are circuits and wirings in the circuit block CB1. The chip 20 is disposed in the circuit block CB2, and hence circuits and wirings in the chip 20 are circuits and wirings in the circuit block CB2. The chip 30 is disposed over the circuit blocks CB1 and CB2. In other words, a part of the chip 30 belongs to the circuit block CB1, while the other part of the chip 30 belongs to the circuit block CB2.

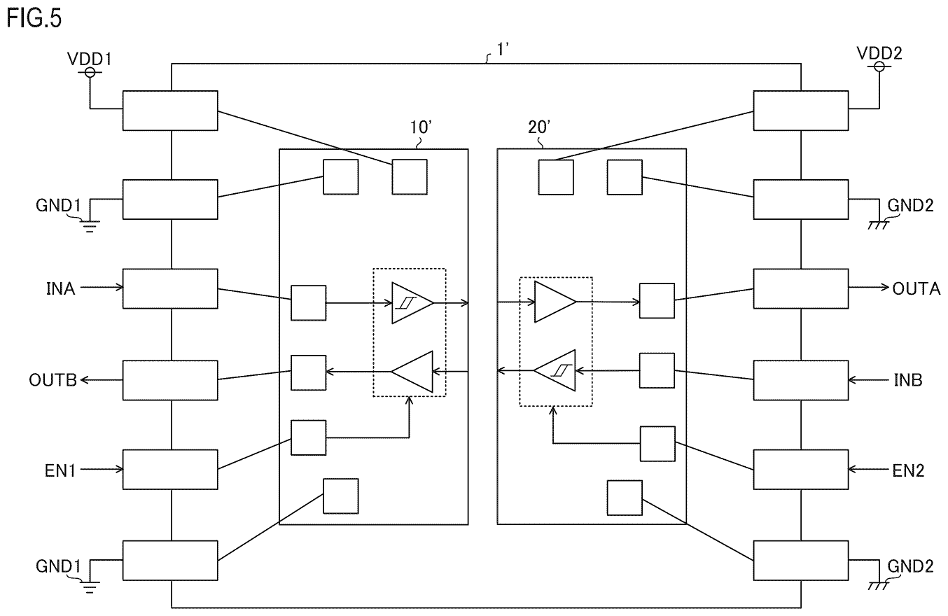

The chips 10, 20 and 30 are disposed in a separated manner from each other. Necessary connections between the chips 10 and 30, and necessary connections between the chips 20 and 30 are realized using wire bondings. In addition, necessary connections between the chip 10 and the external terminals, and necessary connections between the chip 20 and the external terminals are also realized using wire bondings. In FIG. 3, illustration of the wire bondings is omitted. Note that in some drawings (such as FIG. 4) referred to in the following description, illustration of the chip 30 is omitted.

With reference to FIG. 4, in order to describe a positional relationship and the like of the chips 10 and 20, some definitions are given below. A three-dimensional orthogonal coordinate system (an XYZ coordinate system) including an X-axis, a Y-axis and a Z-axis, which are orthogonal to each other, is supposed. The X-axis, the Y-axis and the Z-axis cross each other at an origin O. The origin O is positioned at the center or substantially the center of the case CS. Each of the chips 10 and 20 has a thickness in the Z-axis direction (the same is true for the chip 30). A plane parallel to the X-axis and the Y-axis is referred to as an XY plane. Along the X-axis, a positive side of the X-axis and a negative side of the X-axis are defined with respect to the origin O. In FIG. 4, the right side of the origin O corresponds to the positive side of the X-axis, while the left side of the origin O corresponds to the negative side of the X-axis. Along the Y-axis, the positive side of the Y-axis and the negative side of the Y-axis are defined with respect to the origin O. In FIG. 4, the upper side of the origin O corresponds to the positive side of the Y-axis, while the lower side of the origin O corresponds to the negative side of the Y-axis. The chip 10 is disposed in the negative side region of the X-axis, while the chip 20 is disposed in the positive side region of the X-axis.

The case CS has a substantially rectangular solid shape. Therefore, on the XY plane, the case CS has a substantially rectangular shape, and among four sides constituting the rectangular shape, two sides are sides SD1 and SD2, and the other two sides are sides SD3 and SD4. The sides SD1 and SD2 are parallel to the Y-axis, while the sides SD3 and SD4 are parallel to the X-axis. The sides SD1 and SD2 are two sides that face each other, and all the chips included in the semiconductor device 1 are disposed between the side SD1 and the side SD2. The sides SD3 and SD4 are two sides that face each other, and all the chips included in the semiconductor device 1 are disposed between the side SD3 and the side SD4. The side SD1 is disposed on the negative side of the X-axis, while the side SD2 is disposed on the positive side of the X-axis. Therefore, the chip 10 is disposed between the Y-axis and the side SD1, while the chip 20 is disposed between the Y-axis and the side SD2.

Note that the shape of the case CS on the XY plane is noted here, and in the XYZ coordinate system, the side SD1 corresponds to a first side surface of the case CS, while the side SD2 corresponds to a second side surface of the case CS. The first side surface and the second side surface are two side surfaces facing each other, and the first side surface is positioned in the negative side of the X-axis, while the second side surface is positioned in the positive side of the X-axis.

### [Reference Example]

With reference to FIG. 5, a semiconductor device l′ according to a reference example is described here. The semiconductor device l′ have the same function as the semiconductor device 1 according to this embodiment, but the semiconductor device l′ has an internal structure different from that of the semiconductor device 1. In other words, the semiconductor device l′ has two chips having different structures, as chips 10′ and 20′. When noting the XY plane, the chip 10′ and the chip 20′ have a structure of line symmetry with respect to a symmetry axis that is an axis passing the center between the chips 10′ and 20′.

In the reference example, it is necessary to develop and prepare two types of chips separately. If two chips having the same structure can be used as the chips 10 and 20, necessary development man-hours can be reduced, and further it is possible to enjoy a merit that the number of types of the chips to be manufactured can be reduced. In the semiconductor device 1 according to this embodiment, two chips actually having the same structure are used as the chips 10 and 20.

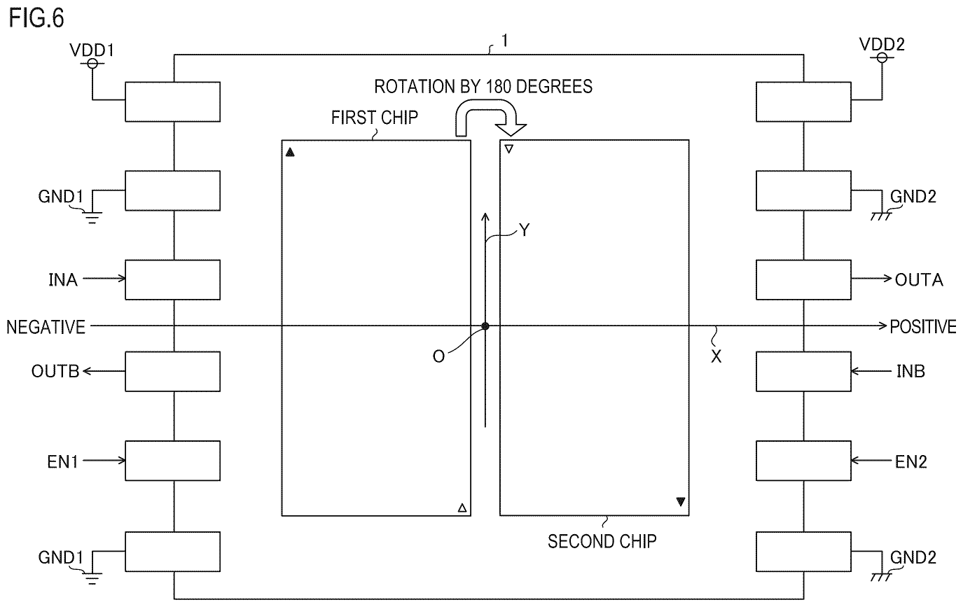

FIG. 6 illustrates a layout concept diagram of chips when commonalization of the chips is aimed. When commonalization of the chips is aimed, the first chip is disposed on the negative side region of the X-axis, and the second chip is disposed on the positive side region of the X-axis. In this case, the first chip is rotated by 180 degrees about a rotation axis that is an axis that passes the origin O and is orthogonal to the XY plane, and the obtained chip is disposed as the second chip on the positive side region of the X-axis. However, in order to aim at commonalization of the chips, it is necessary to devise a pad layout and the like on the chips.

The first embodiment includes following Examples EX1_1 to EX1_7. In Examples EX1_1 to EX1_7, specific structures or related techniques for realizing commonalization of the chips are described. The above description in the first embodiment are applied to following Examples EX1_1 to EX1_7 unless otherwise noted and unless a contradiction arises (but except for matters related to the reference example). If description in each Example conflicts with the above description in the first embodiment, the description in each Example can be given higher priority. In addition, unless a contradiction arises, description in arbitrary Example among Examples EX1_1 to EX1_7 can be applied to another arbitrary Example (i.e., arbitrary two or more Examples among the plurality of Examples can be combined).

### [Example EX1_1]

Example EX1_1 is described below. In Example EX1_1, the semiconductor device 1 according to a basic configuration is described. FIG. 7 illustrates a configuration of the semiconductor device 1 according to Example EX1_1. As described above with reference to FIG. 4, the X-axis and the Y-axis cross at the origin O in reality, but for convenience sake of illustration, FIG. 7 shows the X-axis and the Y-axis shifted from the origin O (the same is true in some other drawings described later in which the X-axis and the Y-axis are shown). In addition, in FIG. 7, the chip 30 is not shown (the same is true in some other drawings described later in which the configuration of the semiconductor device 1 is shown).

Note that in the following description, a voltage having the potential of the ground GND1 may be written as a ground voltage GND1, and a voltage having the potential of the ground GND2 may be written as a ground voltage GND2.

The semiconductor device 1 includes external terminals T11 to T16 and T21 to T26. With reference to FIG. 4 too, the external terminals T11 to T16 belong to a first external terminal group arranged on the side SD1 (in other words, the first external terminal group arranged along the side SD1) and are exposed on the side SD1. In contrast, the external terminals T21 to T26 belong to a second external terminal group arranged on the side SD2 (in other words, the second external terminal group arranged along the side SD2) and are exposed on the side SD2.

The external terminals T11 to T16 are arranged from the positive side to the negative side of the Y-axis in order of the external terminals T11, T12, T13, T14, T15, and T16. Therefore, the external terminals T11 and T12 are adjacent to each other, the external terminals T12 and T13 are adjacent to each other, the external terminals T13 and T14 are adjacent to each other, the external terminals T14 and T15 are adjacent to each other, and the external terminals T15 and T16 are adjacent to each other. Among the external terminals T11 to T16, the external terminal T11 is disposed on the most positive side of the Y-axis, and the external terminal T16 is disposed on the most negative side of the Y-axis.

The external terminals T21 to T26 are arranged from the positive side to the negative side of the Y-axis in order of the external terminals T21, T22, T23, T24, T25, and T26. Therefore, the external terminals T21 and T22 are adjacent to each other, the external terminals T22 and T23 are adjacent to each other, the external terminals T23 and T24 are adjacent to each other, the external terminals T24 and T25 are adjacent to each other, and the external terminals T25 and T26 are adjacent to each other. Among the external terminals T21 to T26, the external terminal T21 is disposed on the most positive side of the Y-axis, and the external terminal T26 is disposed on the most negative side of the Y-axis.

Arrangement positions of the external terminals Tll and T21 have a line-symmetric relationship. Similarly, an arrangement positions of the external terminals T12 and T22 have a line-symmetric relationship, arrangement positions of the external terminals T13 and T23 have a line-symmetric relationship, arrangement positions of the external terminals T14 and T24 have a line-symmetric relationship, arrangement positions of the external terminals T15 and T25 have a line-symmetric relationship, and arrangement positions of the external terminals T16 and T26 have a line-symmetric relationship. On the XY plane, each of the symmetry axes of these line-symmetric relationships is the axis that is parallel to the sides SD1 and SD2 and is positioned at the center between the sides SD1 and SD2, which may coincide with the Y-axis illustrated in FIG. 4.

The external terminal T11 is a power supply terminal that is supplied with the power supply voltage VDD1 from the voltage source VS1. The external terminals T12 and T16 are ground terminals connected to the ground GND1 (and hence are supplied with the ground voltage GND1). The external terminals T13, T14 and T15 are connected to the processing device 2 of FIG. 1. The external terminal T13 is an input terminal that is supplied with the signal INA output from the processing device 2. The signal INA is an input signal to the semiconductor device 1, and is an input signal to a pad P13 described later. The external terminal T14 is an output terminal that outputs the signal OUTB from the semiconductor device 1 to the processing device 2. The external terminal T14 receives an output signal from a pad P14 described later, and the output signal from the pad P14 is sent as the signal OUTB to the processing device 2 via the external terminal T14. The external terminal T15 is a control terminal that receives the signal EN1 output from the processing device 2. The signal EN1 is an example of an external control signal. The signal EN1 is an input signal to the semiconductor device 1, and is an input signal to a pad P15 described later.

The external terminal T21 is a power supply terminal that is supplied with the power supply voltage VDD2 from the voltage source VS2. The external terminals T22 and T26 are ground terminals that are connected to the ground GND2 (and hence are supplied with the ground voltage GND2). The external terminals T23, T24 and T25 are connected to the processing device 3 of FIG. 1. The external terminal T23 is an output terminal that outputs the signal OUTA from the semiconductor device 1 to the processing device 3. The external terminal T23 receives an output signal from a pad P24 described later, and the output signal from the pad P24 is sent as the signal OUTA to the processing device 3 via the external terminal T23. The external terminal T24 is an input terminal that receives the signal INB output from the processing device 3. The signal INB is an input signal to the semiconductor device 1, and is an input signal to a pad P23 described later. The external terminal T25 is a control terminal that receives the signal EN2 output from the processing device 3. The signal EN2 is an example of the external control signal. The signal EN2 is an input signal to the semiconductor device 1, and is an input signal to a pad P26 described later.

The chip 10 includes pads P11 to P18, a functional circuit F11, the internal control signal generation circuit F12, and level adjustment circuits J15 and J16. The functional circuit F11 includes a transmission circuit F11t and a reception circuit F11r. The chip 20 has pads P21 to P28, a functional circuit F21, an internal control signal generation circuit F22, and level adjustment circuits J25 and J26. The functional circuit F21 includes a transmission circuit F2It and a reception circuit F21r.

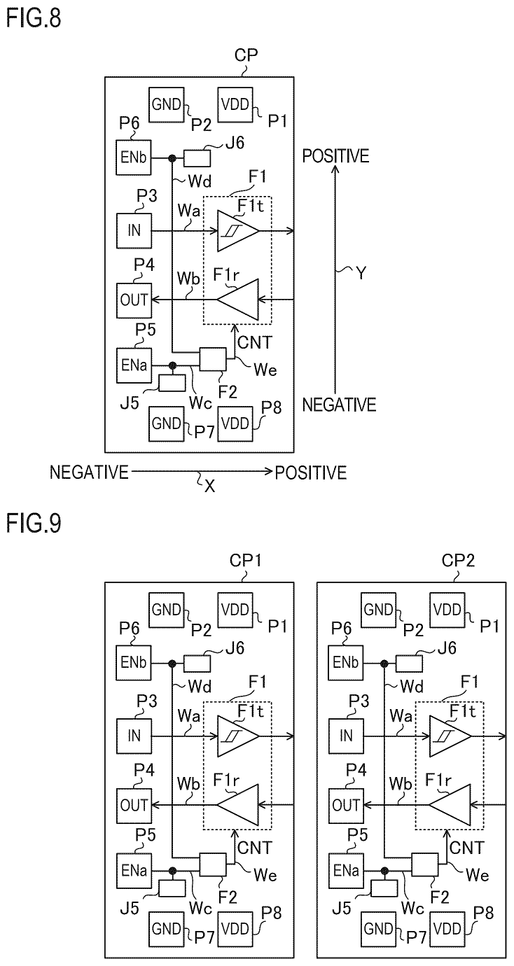

Prior to description of these pad and circuits, a chip CP having the same configuration as the chips 10 and 20 is described. FIG. 8 illustrates a configuration of the chip CP. In the semiconductor device 1, two chips CP having the same structure are used as the chips 10 and 20. The chip CP has a principal surface and a back surface that are parallel to the XY plane, and a plurality of pads are disposed on the principal surface. In the chip CP, out of the principal surface and the back surface, it is supposed that the principal surface is disposed on the positive side of the Z-axis (see FIG. 4). An arbitrary pad is made of metal that is easily connected to a wire. The plurality of pads disposed on the principal surface of the chip CP include pads P1 to P8 that are disposed with spaces in the X-axis direction or the Y-axis direction. In FIG. 8, it is supposed that shapes of the pad on the XY plane are rectangular, but each pad can have an arbitrary shape. The pad P2 is disposed at a position shifted from the arrangement position of the pad P1 in the X-axis direction, and the pad P8 is disposed at a position shifted from the arrangement position of the pad P7 in the X-axis direction. The pads P8 and P7 are disposed at positions shifted from the arrangement positions of the pads P1 and P2 in the Y-axis direction. In FIG. 8, the pads P8 and P7 are disposed on the negative side of the Y-axis with respect to the pads Pl and P2, but the positional relationship thereof can be opposite. Similarly, in FIG. 8, the pads P2 and P7 are disposed on the negative side of the X-axis with respect to the pads P1 and P8, but the positional relationship thereof can be opposite.

The pads P1 and P8 are connected to each other via wirings (not shown) in the chip CP (however, they may not be connected). The pads P2 and P7 are connected to each other via wirings (not shown) in the chip CP (however, they may not be connected). When the chip CP is incorporated as the chip 10 or 20 in the semiconductor device 1, the pads P1 and P8 are applied with a common high-side voltage VDD, while the pads P2 and P7 are applied with a common low-side voltage GND. The high-side voltage VDD is higher than the low-side voltage GND.

The chip CP includes a functional circuit F1, an internal control signal generation circuit F2, and level adjustment circuits J5 and J6. Each of the circuits F1 and F2 is connected to the pad Pl or P8 via a wiring (not shown) in the chip CP so as to be supplied with the high-side voltage VDD, and is connected to the pad P2 or P7 via a wiring (not shown) in the chip CP so as to be supplied with the low-side voltage GND. In the chip CP, arbitrary circuits (including the circuits F1 and F2), which need a power supply voltage, are driven by the high-side voltage VDD as a positive side power supply voltage and the low-side voltage GND as a negative side power supply voltage.

The functional circuit F1 in the chip CP realizes bidirectional communication between itself and another functional circuit of another chip. The functional circuit F1 includes a transmission circuit F1t and a reception circuit F1r. The transmission circuit F1t is connected to the pad P3 via a wiring Wa in the chip CP, and the reception circuit F1r is connected to the pad P4 via a wiring Wb in the chip CP. The pad P3 receives a signal IN from outside of the chip CP. The signal IN is input to the transmission circuit F1t via the pad P3. The pad P4 receives a signal OUT that is output from the reception circuit F1r. The signal OUT is output to the outside of the chip CP via the pad P4.

The signal applied to the pad P5 is a signal ENa, and the signal applied to the pad P6 is a signal ENb. The pad P5 is connected to the circuits J5 and F2 via a wiring Wc in the chip CP. The pad P6 is connected to the circuits J6 and F2 via a wiring Wd in the chip CP. The internal control signal generation circuit F2 generates signal CNT on the basis of voltages of the pads P5 and P6 (in other words, the signals ENa and ENb applied to the pads P5 and P6), and outputs the signal CNT to the functional circuit F1 via a wiring We in the chip CP. Note that the wirings Wa to We are all different from each other. The signal CNT is an example of the internal control signal. In accordance with a level of the signal CNT, a state of the functional circuit F1 is controlled to be ON state or OFF state. If the functional circuit F1 is in ON state, the functional circuit F1 operates, and transmission and reception of signals for the above bidirectional communication is performed by the functional circuit F1. The level adjustment circuits J5 and J6 have a function of adjusting voltages of the pads P5 and P6 (levels of the signals ENa and ENb) so as to adjust the level of the signal CNT to be an appropriate level.

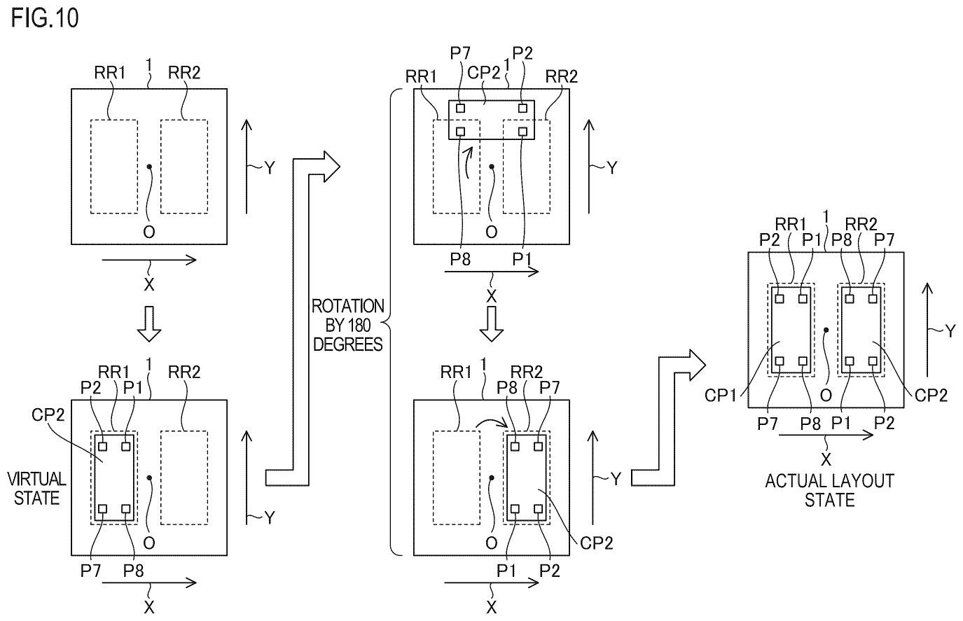

With reference to FIG. 9 and FIG. 10, a positional relationship and a correspondence relationship between two chips CP in the semiconductor device 1 are described. Two chips CP having the same structure are prepared, and as illustrated in FIG. 9, one of the two chips CP is denoted by a symbol “CP1”, and the other is denoted by a symbol “CP2”. FIG. 10 is an explanatory diagram of a layout method of the chips CP1 and CP2 with respect to the semiconductor device 1. In FIG. 10, to prevent complicated illustration, only the pads P1, P2, P7 and P8 are shown among pads of the chips CP1 and CP2.

In FIG. 10, rectangle regions RR1 and RR2 are internal regions of the semiconductor device 1. However, the rectangle region RR1 is a region disposed on the negative side of the X-axis, while the rectangle region RR2 is a region disposed on the positive side of the X-axis. On the XY plane, each of the rectangle regions RR1 and RR2 has the same shape and size as the chip CP, but for convenience sake of illustration in FIG. 10, the size of each of the rectangle regions RR1 and RR2 is shown larger than that of the chip CP. Although the chip CP2 is not disposed in the rectangle region RR1 in reality, a virtual state in which the chip CP2 is disposed in the rectangle region RR1 is assumed. In the virtual state, the pads P1 and P2 of the chip CP2 are disposed at positions shifted from the pads P8 and P7 to the positive side of the Y-axis, and in the chip CP2, the arrangement direction of the pads P1 and P2, and the arrangement direction of the pads P8 and P7 are parallel to the X-axis.

When the chip CP2 is rotated by 180 degrees from the virtual state about the axis that passes the origin O and is orthogonal to the XY plane as the rotation axis, the chip CP2 is disposed in the rectangle region RR2. Further (in the state where the chip CP2 is disposed in the rectangle region RR2), the chip CP1 is disposed in the rectangle region RR1 so that an actual layout state is achieved.

In the chip CP1 in the actual layout state, the pads P1 and P2 are disposed at positions shifted from the pads P8 and P7 to the positive side of the Y-axis, and the arrangement direction of the pads P1 and P2 and the arrangement direction of the pads P8 and P7 are parallel to the X-axis. In the chip CP1 in the actual layout state, the pad P1 is disposed at a position shifted from the pad P2 to the positive side of the X-axis, while the pad P8 is disposed at a position shifted from the pad P7 to the positive side of the X-axis. In the chip CP2 in the actual layout state, the pads P1 and P2 are disposed at positions shifted from the pads P8 and P7 to the negative side of the Y-axis, and the arrangement direction of the pads P1 and P2 and the arrangement direction of the pads P8 and P7 are parallel to the X-axis. In the chip CP2 in the actual layout state, the pad P1 is disposed at a position shifted from the pad P2 to the negative side of the X-axis, and the pad P8 is disposed at a position shifted from the pad P7 to the negative side of the X-axis.

In the semiconductor device 1, the chip 10 corresponds to the chip CP1 in the actual layout state, and the chip 20 corresponds to the chip CP2 in the actual layout state. Therefore, the pads P11 to P18 of the chip 10 respectively correspond to the pads P1 to P8 of the chip CP1 in the actual layout state, and the pads P21 to P28 of the chip 20 respectively correspond to the pads P1 to P8 of the chip CP2 in the actual layout state. The principal surface of the chip 10 and the principal surface of the chip 20 are on the common two-dimensional plane parallel to the XY plane. It is supposed that the chips CP1 and CP2 in the following description mean the chips CP1 and CP2 in the actual layout state, unless otherwise noted.

The circuits F11, F12, J15 and J16 of the chip 10 respectively correspond to the circuits F1, F2, J5 and J6 of the chip CP1, while the circuits F21, F22, J25 and J26 of the chip 20 respectively correspond the circuits F1, F2, J5 and J6 of the chip CP2.

The power supply voltage VDD1 and the ground voltage GND1 in the chip 10 respectively correspond to the high-side voltage VDD and the low-side voltage GND in the chip CP1. The signals INA and OUTB in the chip 10 respectively correspond to the signals IN and OUT in the chip CP1. The power supply voltage VDD2 and the ground voltage GND2 in the chip 20 respectively correspond to the high-side voltage VDD and the low-side voltage GND in the chip CP2. The signals INB and OUTA in the chip 20 respectively correspond to the signals IN and OUT in the chip CP2.

The signals ENa and ENb in the chip CP1 correspond to signals applied to the pads P15 and P16 in the chip 10. The signals ENa and ENb in the chip CP2 correspond to the signals applied to the pads P25 and P26 in the chip 20. The signal CNT1 described later generated in the chip 10 corresponds to the signal CNT in the chip CP1, and the signal CNT2 described later generated in the chip 20 corresponds to the signal CNT in the chip CP2.

The origin O is positioned just in the center between the chips 10 and 20. This will be described in more detail below. A figure obtained by projecting the contour of the chip 10 to the XY plane is referred to as a first figure, and a figure obtained by projecting the contour of the chip 20 to the XY plane is referred to as a second figure. It is supposed that the first figure and the second figure each have a rectangular shape (however, they may have shapes other than a rectangular shape). The origin O is disposed at a middle point between the center of the first figure and the center of the second figure. The second figure is point symmetric to the first figure. In other words, on a two-dimensional plane that includes the origin O and is parallel to the XY plane, the chips 10 and 20 have a point-symmetric relationship with respect to a point (the origin O) positioned between the chip 10 and the chip 20 as a point of symmetry. In a three-dimensional consideration, the chip 10 and the chip 20 have 2-fold symmetric relationship, which is one type of rotational symmetric relationship, with respect to the axis that is parallel to the Z-axis and passes through the origin O, as a symmetry axis (rotation axis). 2-fold symmetry in three-dimensional space is equivalent to line-symmetry.

Note that in FIG. 7 and some drawings referred to later, a black triangle and a white triangle are shown on the chips 10 and 20. The black triangle and the white triangle are shown for indicating the point-symmetric relationship between the chips 10 and 20, for convenience sake, and they are not formed on the real chips 10 and 20.

The configuration of the chip 10 is further described below. The positional relationship of the pads P11 to P18 in the chip 10 is not limited to that described later, but it is supposed here that the pads P11 to P18 are disposed in the chip 10 with the following positional relationship (see FIG. 7). In other words, the pad P12 is disposed at a position shifted from the pad P16 to the positive side of the X-axis and to the positive side of the Y-axis. The pad P11 is disposed at a position shifted from the pad P12 to the positive side of the X-axis. The pad P13 is disposed at a position shifted from the pad P16 to the negative side of the Y-axis. The pad P14 is disposed at a position shifted from the pad P13 to the negative side of the Y-axis. The pad P15 is disposed at a position shifted from the pad P14 to the negative side of the Y-axis. The pad P17 is disposed at a position shifted from the pad P15 to the positive side of the X-axis and the negative side of the Y-axis. The pad P18 is disposed at a position shifted from the pad P17 to the positive side of the X-axis. The pads P11 and P12 are adjacent to each other. The pads P12 and P16 are adjacent to each other. The pads P16 and P13 are adjacent to each other. The pads P13 and P14 are adjacent to each other. The pads P14 and P15 are adjacent to each other. The pads P15 and P17 are adjacent to each other. The pads P17 and P18 are adjacent to each other. If an arbitrary first pad and an arbitrary second pad are adjacent to each other, it can be understood that there is no other pad between the first pad and the second pad.

Wires W11 to W16 are disposed in the semiconductor device 1. The wires W11 to W16 are metal wirings each of which connects a pad on the chip 10 and the corresponding external terminal. By the wire bondings using the wires W11 to W16, the pads P11, P12, P13, P14, P15, and P17 are respectively connected to the external terminals T11, T12, T13, T14, T15, and T16. Specifically, the pad P11 is connected to the external terminal T11 via the wire W11, the pad P12 is connected to the external terminal T12 via the wire W12, the pad P13 is connected to the external terminal T13 via the wire W13, the pad P14 is connected to the external terminal T14 via the wire W14, the pad P15 is connected to the external terminal T15 via the wire W15, and the pad P17 is connected to the external terminal T16 via the wire W16.

For this reason, the pad P11 is applied with the power supply voltage VDD1 via the external terminal T11 and the wire W11, the pad P12 is applied with the ground voltage GND1 via the external terminal T12 and the wire W12, and the pad P17 is applied with the ground voltage GND1 via the external terminal T16 and the wire W16.

The signal INA is applied to the pad P13 via the external terminal T13 and the wire W13. The pad P13 is connected to the transmission circuit F11t via a wiring in the chip 10, and the signal INA at the pad P13 is input to the transmission circuit F11t. The pad P14 is connected to the reception circuit F11r via a wiring in the chip 10, and the output signal of the reception circuit F11r is applied as the signal OUTB to the pad P14. The signal OUTB at the pad P14 is applied to the external terminal T14 via the wire W14, and is output from the external terminal T14 to the processing device 2.

The signal EN1 is applied to the pad P15 via the external terminal T15 and the wire W15. The pad P15 is connected to the circuits F12 and J15 via a wiring in the chip 10 (corresponding to the wiring Wc in FIG. 8). The pads P16 and P18 are not connected to any external terminal. However, the pad P16 may be connected to an external terminal (details will be described later). The pad P16 is connected to the circuits F12 and J16 via a wiring in the chip 10 (corresponding to the wiring Wd in FIG. 8). A signal applied to the pad P15 is particularly referred to as a signal S15, and a signal applied to the pad P16 is particularly referred to as a signal S16.

The internal control signal generation circuit F12 generates the signal CNT1 on the basis of the signals S15 and S16, and outputs the signal CNT1 to the functional circuit F11 via a wiring in the chip 10. The signal CNT1 is an example of the internal control signal. In accordance with a level of the signal CNT1, the state of the functional circuit F11 is controlled to be ON state or OFF state. If the functional circuit F11 is in ON state, the functional circuit F11 operates, and transmission and reception of signals for the above bidirectional communication is performed by the functional circuit F11. The signal CNT1 is a binary signal having high level or low level.

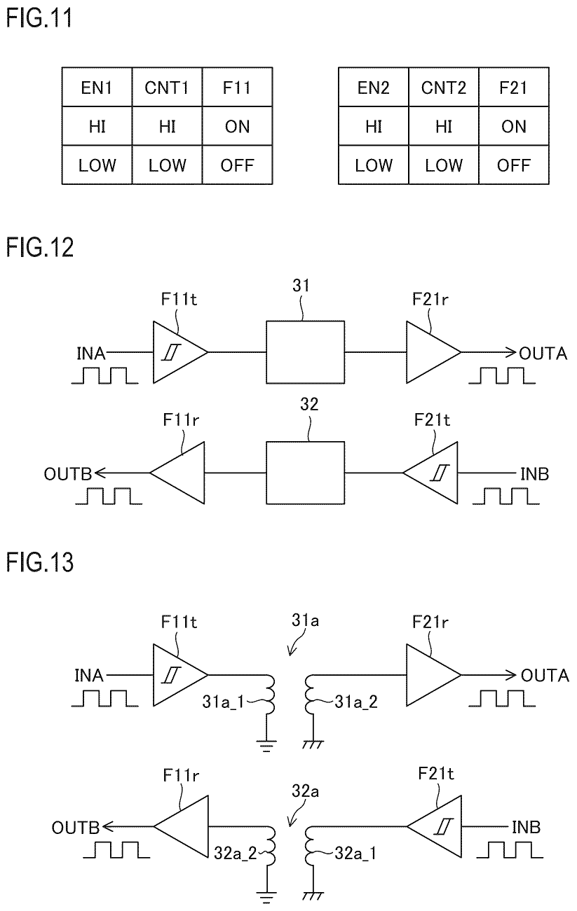

The level adjustment circuits J15 and J16 have a function of adjusting voltages of the pads P15 and P16 (i.e., levels of the signals S15 and S16), so that the signal CNT1 has a level according to the signal EN1. Here, as illustrated in FIG. 11, it is supposed that due to cooperation of the circuits J15, J16 and F12, if the signal EN1 has high level, the signal CNT1 also has high level, while if the signal EN1 has low level, the signal CNT2 also has low level. In addition, it is supposed that if the signal CNT1 has high level, the functional circuit F11 is in ON state, while if the signal CNT1 has low level, the functional circuit F11 is in OFF state. If the functional circuit F11 is in ON state, both the transmission circuit F11t and the reception circuit FIIr operate. If the functional circuit F11 is in OFF state, both the transmission circuit F1lt and the reception circuit F11r stop operation. Alternatively, it may be possible that if the functional circuit F11 is in OFF state, the transmission circuit FlIt operates while the reception circuit Flir stops operation.

The configuration of the chip 20 is further described below. The positional relationship of the pads P21 to P28 in the chip 20 is not limited to that described later, but it is supposed here that the pads P21 to P28 are disposed in the chip 20 with the following positional relationship (see FIG. 7). In other words, the pad P22 is disposed at a position shifted from the pad P26 to the negative side of the X-axis and to the negative side of the Y-axis. The pad P21 is disposed at a position shifted from pad P22 to the negative side of the X-axis. The pad P23 is disposed at a position shifted from the pad P26 to the positive side of the Y-axis. The pad P24 is disposed at a position shifted from the pad P23 to the positive side of the Y-axis. The pad P25 is disposed at a position shifted from the pad P24 to the positive side of the Y-axis. The pad P27 is disposed at a position shifted from pad P25 to the negative side of the X-axis and to the positive side of the Y-axis. The pad P28 is disposed at a position shifted from pad P27 to the negative side of the X-axis. The pads P21 and P22 are adjacent to each other. The pads P22 and P26 are adjacent to each other. The pads P26 and P23 are adjacent to each other. The pads P23 and P24 are adjacent to each other. The pads P24 and P25 are adjacent to each other. The pads P25 and P27 are adjacent to each other. The pads P27 and P28 are adjacent to each other.

Wires W21 to W26 are disposed in the semiconductor device 1. The wires W21 to W26 are metal wirings each of which connects a pad on the chip 20 and the corresponding external terminal. By wire bondings using the wires W21 to W26, the pads P28, P27, P24, P23, P26, and P22 are respectively connected to the external terminals T21, T22, T23, T24, T25, T26. Specifically, the pad P28 is connected to the external terminal T21 via the wire W21, the pad P27 is connected to the external terminal T22 via the wire W22, the pad P24 is connected to the external terminal T23 via the wire W23, the pad P23 is connected to the external terminal T24 via the wire W24, the pad P26 is connected to the external terminal T25 via the wire W25, and the pad P22 is connected to the external terminal T26 via the wire W26.

For this reason, the power supply voltage VDD2 is applied to the pad P28 via the external terminal T21 and the wire W21, the ground voltage GND2 is applied to the pad P27 via the external terminal T22 and the wire W22, and the ground voltage GND2 is applied to the pad P22 via the external terminal T26 and the wire W26.

The pad P24 is connected to the reception circuit F21r via a wiring in the chip 20, and the output signal of the reception circuit F21r is applied as the signal OUTA to the pad P24. The signal OUTA at the pad P24 is applied to the external terminal T23 via the wire W23 and is output from the external terminal T23 to the processing device 3. The signal INB is applied to the pad P23 via the external terminal T24 and the wire W24. The pad P23 is connected to the transmission circuit F21t via a wiring in the chip 20, and the signal INB at the pad P23 is input to the transmission circuit F21t.

The signal EN2 is applied to the pad P26 via the external terminal T25 and the wire W25. The pad P26 is connected to the circuits F22 and J26 via a wiring in the chip 20 (corresponding to the wiring Wd in FIG. 8). The pads P21 and P25 are not connected to any external terminal. However, the pad P25 may be connected to an external terminal (details will be described later). The pad P25 is connected to the circuits F22 and J25 via a wiring in the chip 20 (corresponding to the wiring Wc in FIG. 8). A signal applied to the pad P25 is particularly referred to as a signal S25, and a signal applied to the pad P26 is particularly referred to as a signal S26.

The internal control signal generation circuit F22 generates the signal CNT2 on the basis of the signals S25 and S26, and outputs the signal CNT2 to the functional circuit F21 via a wiring in the chip 20. The signal CNT2 is an example of the internal control signal. In accordance with a level of the signal CNT2, the state of the functional circuit F21 is controlled to be ON state or OFF state. If the functional circuit F21 is in ON state, the functional circuit F21 operates, and transmission and reception of signals for the above bidirectional communication is performed by the functional circuit F21. The signal CNT2 is a binary signal having high level or low level.

The level adjustment circuits J25 and J26 have a function of adjusting voltages of the pads P25 and P26 (i.e., levels of the signals S25 and S26), so that the signal CNT2 has a level according to the signal EN2. Here, as illustrated in FIG. 11, it is supposed that due to cooperation of the circuits J25, J26 and F22, if the signal EN2 has high level, the signal CNT2 also has high level, while if the signal EN2 has low level, the signal CNT2 also has low level. In addition, it is supposed that if the signal CNT2 has high level, the functional circuit F21 is in ON state, while if the signal CNT2 has low level, the functional circuit F21 is in OFF state. If the functional circuit F21 is in ON state, both the transmission circuit F21t and the reception circuit F21r operate. If the functional circuit F21 is in OFF state, both the transmission circuit F21t and the reception circuit F21r stop operation. Alternatively, it may be possible that if the functional circuit F21 is in OFF state, the transmission circuit F21t operates, while the reception circuit F21r stops operation.

Hereinafter, the state where both the signals EN1 and EN2 have high level is referred to as an active state. In the active state, both the functional circuits F11 and F12 are in ON state, and hence the bidirectional communication between the functional circuits F11 and F12 is performed. In the bidirectional communication by the functional circuits F11 and F12, the input signal INA to the pad P13 of the chip 10 is transmitted to the pad P24 of the chip 20, and hence the output signal OUTA is generated at the pad P24, while on the contrary, the input signal INB to the pad P23 of the chip 20 is transmitted to the pad P14 of the chip 10, and hence the output signal OUTB is generated at the pad P14. Note that the bidirectional communication between the functional circuits F11 and F12 is also the bidirectional communication between the processing devices 2 and 3.

FIG. 12 illustrates a configuration related to the bidirectional communication. In the active state, the transmission circuit F11t transmits the signal INA to the reception circuit F21r via an insulation element 31, and the reception circuit F21r generates the signal OUTA on the basis of the signal received by the reception circuit F21r. Here, it is supposed that the reception circuit F21r outputs the signal OUTA having high level when the signal INA has high level, while it outputs the signal OUTA having low level when the signal INA has low level (although, it may be possible to modify the level relationship to be opposite). In the active state, the transmission circuit F21t sends the signal INB to the reception circuit F11r via an insulation element 32, and the signal OUTB is generated by the reception circuit F11r on the basis of the signal received by the reception circuit F11r. Here, it is supposed that the reception circuit F11r outputs the signal OUTB having high level when the signal INB has high level, while it outputs the signal OUTB having low level when the signal INB has low level (although, it may be possible to modify the level relationship to be opposite).

The insulation elements 31 and 32 are disposed in the chip 30 (see FIG. 3). The bidirectional communication between the functional circuits F11 and F12 may be realized using a magnetic insulation method. In this case, as illustrated in FIG. 13, the insulation element 31 is constituted of a pulse transformer 31a having a primary winding 31a_1 and a secondary winding 31a_2, while the insulation element 32 is constituted of a pulse transformer 32a having a primary winding 32a_1 and a secondary winding 32a_2. The primary winding 31a_1 and the secondary winding 32a_2 belong to configuration elements in the circuit block CB1, while the secondary winding 31a_2 and the primary winding 32a_1 belong to configuration elements in the circuit block CB2 (see FIG. 1, too). Further, the transmission circuit F11t supplies current to the primary winding 31a_1 in accordance with the signal INA and allows the secondary winding 31a_2 to induce a voltage corresponding to the signal INA, and the reception circuit F21r reads the induced voltage on the secondary winding 31a_2, so that the signal OUTA is generated. Similarly, the transmission circuit F21t supplies current to the primary winding 32a_1 in accordance with the signal INB and allows the secondary winding 32a_2 to induce a voltage corresponding to the signal INB, and the reception circuit FIIr reads the induced voltage on the secondary winding 32a_2, so that the signal OUTB is generated.

The insulation element 31 may separately include a pulse transformer for transmitting a switching of the signal INA from low level to high level, and a pulse transformer for transmitting a switching of the signal INA from high level to low level. Similarly, the insulation element 32 may separately include a pulse transformer for transmitting a switching of the signal INB from low level to high level, and a pulse transformer for transmitting a switching of the signal INB from high level to low level.

Alternatively, the bidirectional communication between the functional circuits F11 and F12 may be realized using a capacitive insulation method. In this case, each of the insulation elements 31 and 32 is constituted of a capacitor.

Note that the insulation elements 31 and 32 may be disposed so as to be distributed to the chips 10 and 20. In other words, for example, if the insulation elements 31 and 32 are constituted of the pulse transformers 31a and 32a, the primary winding 31a_1 and the secondary winding 32a_2 may be disposed in the chip 10, while the secondary winding 31a_2 and the primary winding 32a_1 may be disposed in the chip 20. In this case, the chip 30 is not disposed in the semiconductor device 1. The same is true in the case where the capacitive insulation method is adopted.

As described above, the power supply voltage VDD1 and the ground voltage GND1 function as the high-side voltage VDD and the low-side voltage GND in the chip 10. As described above, the power supply voltage VDD2 and the ground voltage GND2 function as the high-side voltage VDD and the low-side voltage GND in the chip 20. In each chip, the pad to which the high-side voltage VDD is applied can be referred to as a high-side pad. The pads P11 and P28 are high-side pads. In each chip, the pad to which the low-side voltage GND is applied can be referred to as a low-side pad. The pads P12, P17, P22 and P27 are low-side pads. The pad to which the input signal (INA, INB) to the semiconductor device 1 is applied can be referred to as an input pad. The pads P13 and P23 are input pads. The pad to which the output signal (OUTA, OUTB) from the semiconductor device 1 is applied can be referred to as an output pad. The pads P14 and P24 are output pads.

In each chip, two or more control pads are disposed, and the internal control signal (CNT1 or CNT2) is generated on the basis of two or more signals applied to the two or more control pads. In the configuration of FIG. 7, the pads P15 and P16 are two control pads in the chip 10, and the pads P25 and P26 are two control pads in the chip 20. In each chip, the external control signal (EN1 or EN2) is input to one of the two or more control pads. One of the two or more control pads, which receives the external control signal is referred to as a target control pad, and the other control pads are referred to as non-target control pads. In the configuration of FIG. 7, the pad P15 is the target control pad that receives the signal EN1 as the external control signal, and the pad P26 is the target control pad that receives the signal EN2 as the external control signal. The pads P16 and P25 are non-target control pads.

### [Example EX1_2]

Example EX1_2 is described below. Example EX1_2 and Examples EX1_3 to EX1_7 described later are Examples based on Example EX1_1, and description of Example EX1_1 is also applied to Examples EX1_2 to EX1_7 about matters that are not particularly noted in Examples EX1_2 to EX1_7, unless a contradiction arises. However, when interpreting description of Example EX1_2, if there is a conflict between Examples EX1_1 and EX1_2, description of Example EX1_2 can be given higher priority (the same is true for Examples EX1_3 to EX1_7 described later). Unless a contradiction arises, arbitrary plurality of Examples among Examples EX1_1 to EX1_7 may be combined.

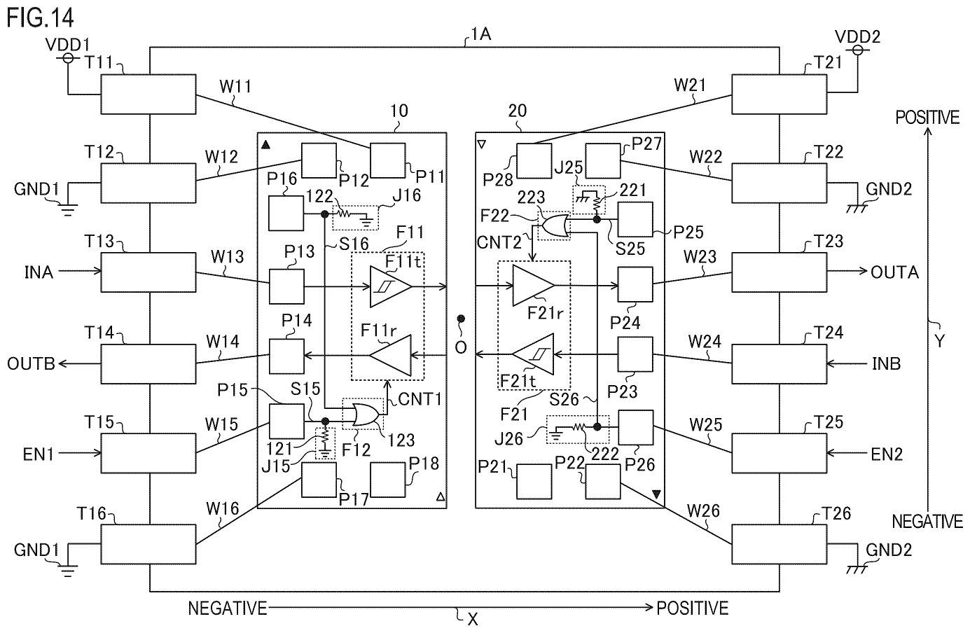

FIG. 14 illustrates a configuration of a semiconductor device 1A that is the semiconductor device 1 according to Example EX1_2. In the chip 10 of the semiconductor device 1A, the level adjustment circuit J15 is constituted of a pull-down resistor 121, the level adjustment circuit J16 is constituted of a pull-down resistor 122, and the internal control signal generation circuit F12 is constituted of an OR circuit 123. Because the chip 20 has the same structure as the chip 10, also in the chip 20 of the semiconductor device 1A, each level adjustment circuit is constituted of a pull-down resistor, and the internal control signal generation circuit is constituted of an OR circuit. Specifically, in the chip 20 of the semiconductor device 1A, the level adjustment circuit J25 is constituted of a pull-down resistor 221, the level adjustment circuit J26 is constituted of a pull-down resistor 222, and the internal control signal generation circuit F22 is constituted of an OR circuit 223.

A first terminal of the pull-down resistor 121 is connected to the pad P15, and a second terminal of the pull-down resistor 121 is applied with the ground voltage GND1. A first terminal of the pull-down resistor 122 is connected to the pad P16, and a second terminal of the pull-down resistor 122 is applied with the ground voltage GND1. The OR circuit 123 is a 2-input OR circuit and receives the signals S15 and S16 applied to the pads P15 and P16 as its own input signals. The OR circuit 123 outputs an OR signal of the signals S15 and S16 as the signal CNT1. Therefore, the OR circuit 123 outputs the signal CNT1 of high level when at least one of the signals S15 and S16 has high level, while it outputs the signal CNT1 of low level when both the signals S15 and S16 have low level.

Because the level of the signal S16 is fixed to low level by the pull-down resistor 122, the level of the signal CNT1 is determined depending on only the level of the signal S15. Because the level of the signal S15 is the same as the level of the signal EN1, in the semiconductor device 1A, if the signal EN1 is at high level, the signal CNT1 is also at high level, while if the signal EN1 is at low level, the signal CNT1 is also at low level.

A first terminal of the pull-down resistor 221 is connected to the pad P25, and a second terminal of the pull-down resistor 221 is applied with the ground voltage GND2. A first terminal of the pull-down resistor 222 is connected to the pad P26, and a second terminal of the pull-down resistor 222 is applied with the ground voltage GND2. The OR circuit 223 is a 2-input OR circuit, and receives the signals S25 and S26 applied to the pads P25 and P26 as its own input signals. The OR circuit 223 outputs an OR signal of the signals S25 and S26 as the signal CNT2. Therefore, the OR circuit 223 outputs the signal CNT2 of high level if at least one of the signals S25 and S26 has high level, while it outputs the signal CNT2 of low level if both the signals S25 and S26 have low level.

Because the level of the signal S25 is fixed to low level by the pull-down resistor 221, the level of the signal CNT2 is determined depending on only the level of the signal S26. Because the level of the signal S26 corresponds to the level of the signal EN2, in the semiconductor device 1A, if the signal EN2 has high level, the signal CNT2 also has high level, while if the signal EN2 has low level, the signal CNT2 also has low level.

In this way, in Example EX1_2, each control pad in each of the chips 10 and 20 is pulled down to the low-side voltage GND. In other words, the pads P15 and P16 are pulled down to the ground voltage GND1, and the pads P25 and P26 are pulled down to the ground voltage GND2. Further, in each of the chips 10 and 20, the OR signal of the signals applied to the two or more control pads (here, the two control pads) is generated as the internal control signal (CNT1, CNT2). In this way, even if the semiconductor device 1 (1A) is constituted using the common two chips, it is possible to allow the functional circuits F11 and F21 to correctly operate.

### [Example EX1_3]

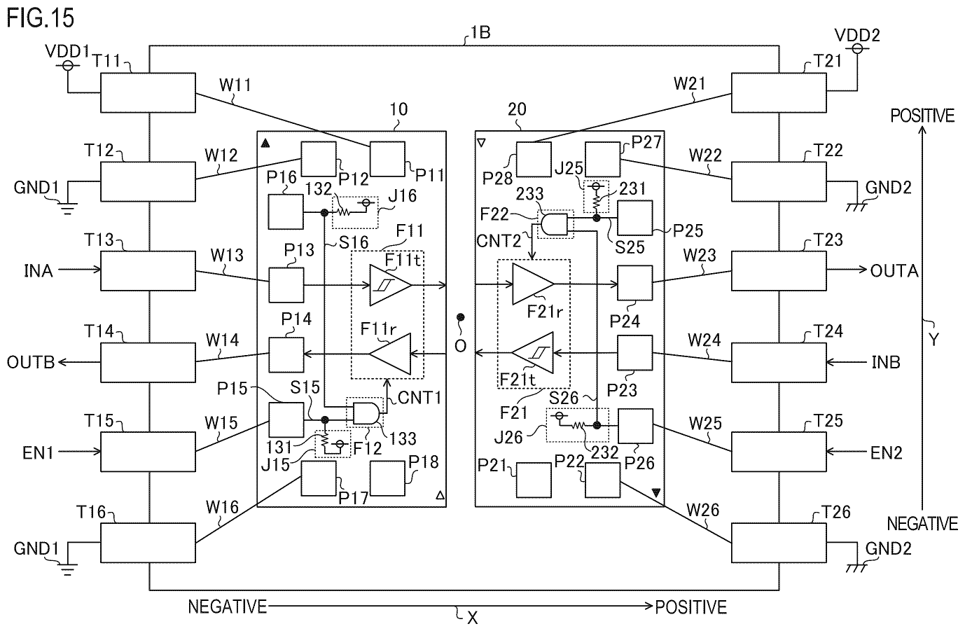

Example EX1_3 is described below. FIG. 15 illustrates a configuration of a semiconductor device 1B that is the semiconductor device 1 according to Example EX1_3. In the chip 10 of the semiconductor device 1B, the level adjustment circuit J15 is constituted of a pull-up resistor 131, and the level adjustment circuit J16 is constituted of a pull-up resistor 132, and the internal control signal generation circuit F12 is constituted of an AND circuit 133. Because the chip 20 has the same structure as the chip 10, also in the chip 20 of the semiconductor device 1B, each level adjustment circuit is constituted of a pull-up resistor, and the internal control signal generation circuit is constituted of an AND circuit. Specifically, in the chip 20 of the semiconductor device 1B, the level adjustment circuit J25 is constituted of a pull-up resistor 231, the level adjustment circuit J26 is constituted of a pull-up resistor 232, and the internal control signal generation circuit F22 is constituted of an AND circuit 233.

A first terminal of the pull-up resistor 131 is connected to the pad P15, and a second terminal of the pull-up resistor 131 is applied with the power supply voltage VDDI. A first terminal of the pull-up resistor 132 is connected to the pad P16, and a second terminal of the pull-up resistor 132 is applied with the power supply voltage VDD1. The AND circuit 133 is a 2-input AND circuit and receives the signals S15 and S16 applied to the pads P15 and P16 as its own input signals. The AND circuit 133 outputs an AND signal of the signals S15 and S16 as the signal CNT1. Therefore, the AND circuit 133 outputs the signal CNT1 of high level only in the case where both the signals S15 and S16 have high level, while it outputs the signal CNT1 of low level if at least one of the signals S15 and S16 has low level.

Because the level of the signal S16 is fixed to high level by the pull-up resistor 132, the level of the signal CNT1 is determined depending on only the level of the signal S15. Because the level of the signal S15 corresponds to the level of the signal EN1, in the semiconductor device 1B, if the signal EN1 has high level, the signal CNT1 also has high level, while if the signal EN1 has low level, the signal CNT1 also has low level.

A first terminal of the pull-up resistor 231 is connected to the pad P25, and a second terminal of the pull-up resistor 231 is applied with the power supply voltage VDD2. A first terminal of the pull-up resistor 232 is connected to the pad P26, and a second terminal of the pull-up resistor 232 is applied with the power supply voltage VDD2. The AND circuit 233 is a 2-input AND circuit and receives the signals S25 and S26 applied to the pads P25 and P26 as its own input signals. The AND circuit 233 outputs an AND signal of the signals S25 and S26 as the signal CNT2. Therefore, the AND circuit 233 outputs the signal CNT2 of high level only in the case where both the signals S25 and S26 have high level, and outputs the signal CNT2 of low level if at least one of the signals S25 and S26 has low level.

Because the level of the signal S25 is fixed to high level by the pull-up resistor 231, the level of the signal CNT2 is determined depending on only the level of the signal S26. Because the level of the signal S26 corresponds to the level of the signal EN2, in the semiconductor device 1B, if the signal EN2 has high level, the signal CNT2 also has high level, while if the signal EN2 has low level, the signal CNT2 also has low level.

In this way, in Example EX1_3, each control pad in each of the chips 10 and 20 is pulled up to the high-side voltage VDD. In other words, the pads P15 and P16 are pulled up to the power supply voltage VDD1, and the pads P25 and P26 are pulled up to the power supply voltage VDD2. Further, in each of the chips 10 and 20, the AND signal of the signals applied to the two or more control pads (here, the two control pads) is generated as the internal control signal (CNT1, CNT2). In this way, even if the semiconductor device 1 (1B) is constituted using the common two chips, it is possible to allow the functional circuits F11 and F21 to correctly operate.

In the above description of Example EX1_3, it is supposed that a stable power supply state is maintained. The power supply state means a state where a supply voltage to the external terminal T11 is a prescribed voltage V_{N1} or more, and a supply voltage to the external terminal T21 is a prescribed voltage V_{N2} or more. The prescribed voltage V_{N1} corresponds to the minimum power supply voltage VDD1 necessary for allowing the semiconductor device 1 to correctly operate, and the prescribed voltage V_{N2} corresponds to the minimum power supply voltage VDD2 necessary for allowing the semiconductor device 1 to correctly operate. The prescribed voltages V_{N1} and V_{N2} both have a positive voltage value. If the operation of the semiconductor device 1 is not necessary for a purpose of power saving or the like, the power supply to the semiconductor device 1 may be stopped. The state where the power supply to the semiconductor device 1 is stopped is referred to as a power-stopped state. In the power-stopped state, “VDD1<V_{N1}” and “VDD2<V_{N2}” hold, and typically the supply voltages to the external terminals T11 and T21 are both 0 V.

The state where the supply voltages to the external terminals T11 and T21 are 0 V corresponds to the state where the power supply voltages VDD1 and VDD2 are 0 V, and hence in the semiconductor device 1B in this state, the signal S16 has the ground voltage GND1, and the signal S25 has the ground voltage GND2.

In the semiconductor device 1B, if the supply voltage (VDD1) to the external terminal T11 rapidly increases from 0 V to the prescribed voltage VN1 or more, a positive charge is supplied to the wiring applied with the signal S16 via the pull-up resistor 132, and hence the signal S16 is gradually increased, so that the signal S16 reaches a level belonging to high level after a decent delay time. In other words, before the delay time elapses, the level of the signal EN1 is not transmitted to the signal CNT1, and operation control of the functional circuit F11 according to the level of the signal EN1 cannot be obtained. Similarly, in the semiconductor device 1B, if the supply voltage (VDD2) to the external terminal T21 rapidly increases from 0 V to the prescribed voltage V_{N2} or more, a positive charge is supplied to the wiring applied with the signal S25 via the pull-up resistor 231, and hence the signal S25 is gradually increased, so that the signal S25 reaches a level belonging to high level after a decent delay time. In other words, before the delay time elapses, the level of the signal EN2 is not transmitted to the signal CNT2, and operation control of the functional circuit F21 according to the level of the signal EN2 cannot be obtained.

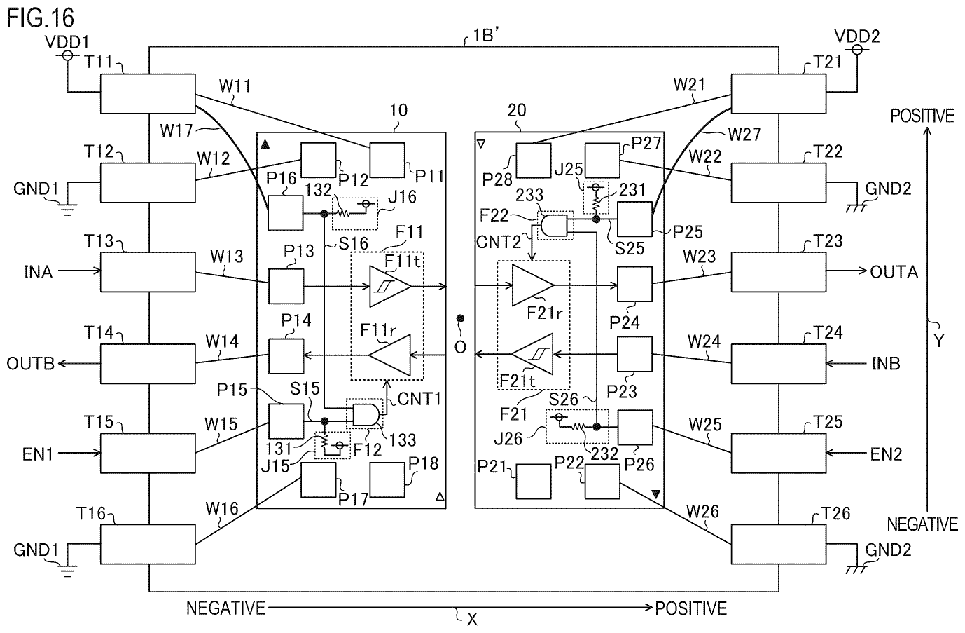

In this way, the semiconductor device 1B is not good at increasing the startup speed. In order to solve this, it may be possible to modify the semiconductor device 1B to be a semiconductor device 1B′ of FIG. 16. On the basis of the semiconductor device 1B of FIG. 15, by adding wires W17 and W27, the semiconductor device 1B′ of FIG. 16 can be obtained. In the semiconductor device 1B′, the wire W17 is a metal wiring that connects the external terminal T11 and the pad P16, while the wire W27 is a metal wiring that connects the external terminal T21 and the pad P25, and the connections can be realized by well-known wire bonding. In other words, in the semiconductor device 1B′, the pads P11 and P16 in the chip 10 are commonly connected to the external terminal T11 using the wire bonding, so as to receive the power supply voltage VDD1 (the high-side voltage VDD of the chip 10), and the pads P28 and P25 in the chip 20 are commonly connected to the external terminal T21 using the wire bonding, so as to receive the power supply voltage VDD2 (the high-side voltage VDD of the chip 20). According to the semiconductor device 1B′, the increase of the supply voltage (VDD1) to the external terminal T11 is promptly reflected on the signal S16, while the increase of the supply voltage (VDD2) to the external terminal T21 is promptly reflected on the signal S25, and hence it is possible to realize fast startup.

However, in the semiconductor device 1B′, projected figures of the wires W12 and W17 on the XY plane cross each other, and projected figures of the wires W22 and W27 on the XY plane cross each other. For this reason, it is necessary to attend so that the wires W12 and W17 do not contact each other in the case CS, and it is necessary to attend so that the wires W22 and W27 do not contact each other in the case CS of the semiconductor device 1.

It may be possible to change the arrangement positions of the pads or the arrangement positions of the external terminals, so that the crossings described above do not occur.

### [Example EX1_4]

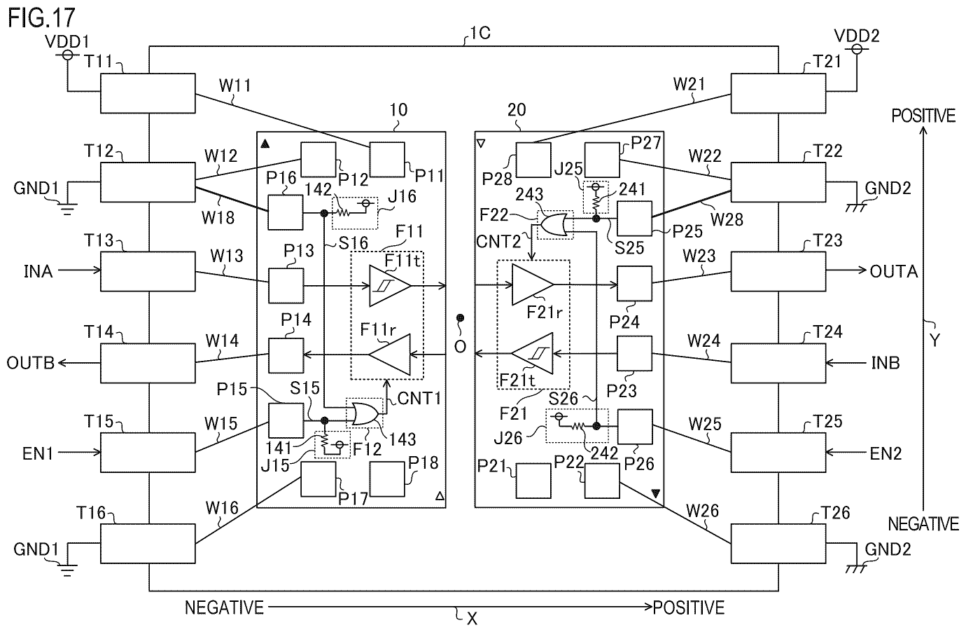

Example EX1_4 is described below. FIG. 17 illustrates a configuration of a semiconductor device IC that is the semiconductor device 1 according to Example EX1_4. In the chip 10 of the semiconductor device IC, the level adjustment circuit J15 is constituted of a pull-up resistor 141, and the level adjustment circuit J16 is constituted of a pull-up resistor 142, and the internal control signal generation circuit F12 is constituted of an OR circuit 143. Because the chip 20 has the same structure as the chip 10, also in the chip 20 of the semiconductor device IC, each level adjustment circuit is constituted of a pull-up resistor, and the internal control signal generation circuit is constituted of an OR circuit. Specifically, in the chip 20 of the semiconductor device IC, the level adjustment circuit J25 is constituted of a pull-up resistor 241, the level adjustment circuit J26 is constituted of a pull-up resistor 242, and the internal control signal generation circuit F22 is constituted of an OR circuit 243.

A first terminal of the pull-up resistor 141 is connected to the pad P15, and a second terminal of the pull-up resistor 141 is applied with the power supply voltage VDD1. A first terminal of the pull-up resistor 142 is connected to the pad P16, and a second terminal of the pull-up resistor 142 is applied with the power supply voltage VDD1. The OR circuit 143 is a 2-input OR circuit and receives the signals S15 and S16 applied to the pads P15 and P16 as its own input signals. The OR circuit 143 outputs an OR signal of the signals S15 and S16 as the signal CNT1. Therefore, the OR circuit 143 outputs the signal CNT1 of high level if at least one of the signals S15 and S16 has high level, while it outputs the signal CNT1 of low level if both the signals S15 and S16 have low level.

In view of the configuration of FIG. 7, a wire W18 is added to the semiconductor device 1C. The wire W18 is a metal wiring that connects the external terminals T12 and the pad P16, and this connection is realized by well-known wire bonding. In other words, in the semiconductor device 1C, the pads P12 and P16 in the chip 10 are commonly connected to the external terminal T12 using wire bonding so as to receive the ground voltage GND1 (the low-side voltage GND of the chip 10). In the chip 10, there is the pull-up resistor 142, but because the pad P16 that functions as a non-target control pad is connected to the external terminal T12 by wire bonding, the level of the signal S16 is fixed to low level. Therefore, the level of the signal CNT1 is determined depending on only the level of the signal S15. Because the level of the signal S15 corresponds to the level of the signal EN1, in the semiconductor device 1C, if the signal EN1 has high level, the signal CNT1 also has high level, while if the signal EN1 has low level, the signal CNT1 also has low level.

A first terminal of the pull-up resistor 241 is connected to the pad P25, and a second terminal of the pull-up resistor 241 is applied with the power supply voltage VDD2. A first terminal of the pull-up resistor 242 is connected to the pad P26, and a second terminal of the pull-up resistor 242 is applied with the power supply voltage VDD2. The OR circuit 243 is a 2-input OR circuit and receives the signals S25 and S26 applied to the pads P25 and P26 as its own input signals. The OR circuit 243 outputs an OR signal of the signals S25 and S26 as the signal CNT2. Therefore, the OR circuit 243 outputs the signal CNT2 of high level if at least one of the signals S25 and S26 has high level, while it outputs the signal CNT2 of low level if both the signals S25 and S26 have low level.

In view of the configuration of FIG. 7, a wire W28 is added to the semiconductor device 1C. The wire W28 is a metal wiring that connects the external terminals T22 and pad P25, and this connection is realized by well-known wire bonding. In other words, in the semiconductor device IC, the pads P27 and P25 in the chip 20 are commonly connected to the external terminal T22 using wire bonding, so as to receive the ground voltage GND2 (the low-side voltage GND of the chip 20). In the chip 20, there is the pull-up resistor 241, but because the pad P25 that functions as a non-target control pad is connected to the external terminal T22 by wire bonding, the level of the signal S25 is fixed to low level. Therefore, the level of the signal CNT2 is determined depending on only the level of the signal S26. Because the level of the signal S26 corresponds to the level of the signal EN2, in the semiconductor device IC, if the signal EN2 has high level, the signal CNT2 also has high level, while if the signal EN2 has low level, the signal CNT2 also has low level.

In this way, in Example EX1_4, each control pad in each of the chips 10 and 20 is pulled up to the high-side voltage VDD. In other words, the pads P15 and P16 are pulled up to the power supply voltage VDD1, and the pads P25 and P26 are pulled up to the power supply voltage VDD2. Further, in each of the chips 10 and 20, the OR signal of the signals applied to the two or more control pads (here, the two control pads) is generated as the internal control signal (CNT1, CNT2). Further, in the chip 10, the low-side pad (P12) and the non-target control pad (P16) are commonly connected to the external terminal T12, while in the chip 20, the low-side pad (P27) and the non-target control pad (P25) are commonly connected to the external terminal T22. In this way, even if the semiconductor device 1 (1C) is constituted using the common two chips, it is possible to allow the functional circuits F11 and F21 to correctly operate. In addition, the delay described above related to the semiconductor device 1B (see FIG. 15) does not occur, and hence it is possible to realize fast startup.

In the semiconductor device IC, projected figures of the wires W12 and W18 on the XY plane do not cross each other, and projected figures of the wires W22 and W28 on the XY plane do not cross each other. For this reason, contact between the wires W12 and W18 in the case CS can be easily avoided. The same is true for the wires W22 and W28.

Note that there may be a case where the external terminals T12 and the pad P16 are not connected to each other due to disconnection or poor connection of the wire W18. In this case, ON/OFF switching of the functional circuit F11 by the signal EN1 is disabled (the functional circuit F11 is fixed to ON state). For this reason, it is possible to easily detect disconnection or poor connection of the wire W18. The same is true for disconnection or poor connection of the wire W28. In other words, for example, it is possible to perform a test on the semiconductor device 1C, in which the level of the signal INA or INB is changed while the signals EN1 and EN2 are fixed to low level. Then, in this test, it is checked whether or not there is a change in the level of the signal OUTA or OUTB in synchronization with the change of the level of the signal INA or INB, so that presence or absence of disconnection or poor connection of the wire W18 or W28 can be detected.

### [Example EX1_5]

Example EX1_5 is described below. The semiconductor device 1 is provided with leads equal in number to the number of external terminals. Each lead disposed in the semiconductor device 1 is constituted of a metal part inside the case CS and a metal part exposed from the case CS, and the former metal part is referred to as an inner lead while the latter metal part is referred to as an outer lead. In each lead, the outer lead functions as the corresponding external terminal. Depending on a type of the case CS, the outer lead protrudes as a pin-shaped external terminal from the case CS. Each lead is constituted of a thin metal plate having a thickness in the Z-axis direction. The lead is made of copper. However, the lead may be made of a metal other than copper. For instance, the lead may be made of so-called 42 Alloy (an alloy in which nickel is added to iron). The wire used for wire bonding is a metal wire made of gold, aluminum, or copper.

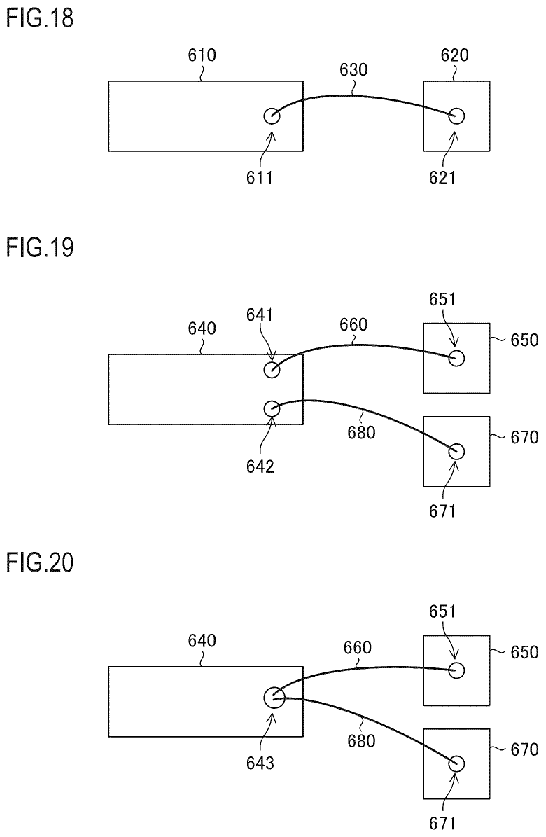

In FIG. 18, a lead 610 is an arbitrary lead disposed in the semiconductor device 1, and a pad 620 is a pad to be connected to the lead 610 via a wire 630 (a pad on the chip 10 or 20). For instance, in the semiconductor device 1 of FIG. 7, if the lead 610 is a lead constituting the external terminal T11, the pad 620 and the wire 630 are the pad P11 and the wire W11, while if the lead 610 is a lead constituting the external terminal T12, the pad 620 and the wire 630 are the pad P12 and the wire W12. When the lead 610 is connected with the pad 620, one end of the wire 630 is electrically connected to the lead 610 at a bonding part 611 on the lead 610, and the other end of the wire 630 is electrically connected to the pad 620 at a bonding part 621 on the pad 620. The bonding part 611 is on the inner lead of the lead 610.

With reference to FIG. 19 and FIG. 20, described is a method of connecting two pads on the chip to a single external terminal with wire bonding. Each of FIG. 19 and FIG. 20 illustrates a manner where a pad 650 is connected to a lead 640 via a wire 660, and a pad 670 is connected to the lead 640 via a wire 680.

In the semiconductor device 1B′ of FIG. 16, the lead 640 may be a lead constituting the external terminal T11, and in this case, the pads 650 and 670 are the pads P11 and P16. In the semiconductor device 1B′ of FIG. 16, the lead 640 may be a lead constituting the external terminal T21, and in this case, the pads 650 and 670 are the pads P25 and P28. In the semiconductor device 1C of FIG. 17, the lead 640 may be a lead constituting the external terminal T12, and in this case, the pads 650 and 670 are the pads P12 and P16. In the semiconductor device IC of FIG. 17, the lead 640 may be a lead constituting the external terminal T22, and in this case, the pads 650 and 670 are pads P25 and P27.

A first connection method is adopted in FIG. 19, and a second connection method is adopted in FIG. 20. In the semiconductor devices 1B′ and 1C, either one of the first and the second connection methods may be adopted.

First, the first connection method of FIG. 19 is described. In the first connection method of FIG. 19, an end of the wire 660 is electrically connected to the lead 640 at a bonding part 641 on the lead 640, and the other end of the wire 660 is electrically connected to the pad 650 at a bonding part 651 on the pad 650. In the first connection method of FIG. 19, an end of the wire 680 is electrically connected to the lead 640 at a bonding part 642 on the lead 640, and the other end of the wire 680 is electrically connected to the pad 670 at a bonding part 671 of the pad 670. The bonding parts 641 and 642 are on the inner lead of the lead 640. In the first connection method, bonding of the wire 680 to the lead 640 is performed separately from bonding of the wire 660 to the lead 640, and the bonding parts 641 and 642 are apart from each other.

The second connection method of FIG. 20 is described. In the second connection method of FIG. 20, an end of the wire 660 is electrically connected to the lead 640 at a bonding part 643 on the lead 640, and the other end of the wire 660 is electrically connected to the pad 650 at the bonding part 651 on the pad 650. In the second connection method of FIG. 20, an end of the wire 680 is electrically connected to the lead 640 at the bonding part 643 on the lead 640, and the other end of the wire 680 is electrically connected to the pad 670 at the bonding part 671 on the pad 670. The bonding part 643 is on the inner lead of the lead 640. In the second connection method, the bonding part between the wire 660 and the lead 640 and the bonding part between the wire 680 and the lead 640 are the same one. In the second connection method, the bonding of the wire 660 to the lead 640 and the bonding of the wire 680 to the lead 640 may be performed in a lump.

### [Example EX1_6]

Example EX1_6 is described below. As described above, two or more control pads are disposed in each chip, and the internal control signal (CNT1 or CNT2) is generated on the basis of two or more signals applied to the two or more control pads. In the configuration of FIG. 7, the pads P15 and P16 are the two control pads in the chip 10, while the pads P25 and P26 are the two control pads in the chip 20.

Three or more control pads may be disposed in each of the chips 10 and 20. In this case, in each chip, the external control signal (EN1 or EN2) is input to one of the three or more control pads. The control pad that receives the external control signal functions as the target control pad, and the other control pads function as non-target control pads.

Also in the case where three or more control pads are disposed in the chip 10, using the method described above in any one of Examples EX1_2 to EX1_4, each control pad in the chip 10 is pulled up to the power supply voltage VDD1 or pulled down to the ground voltage GND1, and the signal CNT1 is generated on the basis of signals applied to control pads in the chip 10 (i.e., three or more signal applied to three or more control pads in the chip 10).

For instance, in the chip 10, a first modification technique is supposed in which a pad P_{ADD1} (not shown) as a third control pad is added to the pads P15 and P16 as the first and second control pads.

When the first modification technique is applied to the configuration of FIG. 14, the pad P_{ADD1} is not connected to any one of the external terminals, the pad P_{ADD1} is connected to an end of a not-shown pull-down resistor, and the other end of the pull-down resistor is applied with the ground voltage GND1. Further, the circuit F12 generates an OR signal of three signals at the pads P15, P16 and P_{ADD1} as the signal CNT1.

When the first modification technique is applied to the configuration of FIG. 15, the pad P_{ADD1} is not connected to any one of the external terminals, the pad P_{ADD1} is connected to an end of a not-shown pull-up resistor, and the other end of the pull-up resistor is applied with the power supply voltage VDD1. Further, the circuit F12 generates an AND signal of three signals at the pads P15, P16 and P_{ADD1} as the signal CNT1.

When the first modification technique is applied to the configuration of FIG. 16, the pad P_{ADD1} is connected to an end of a not-shown pull-up resistor, and the other end of the pull-up resistor is applied with the power supply voltage VDD1. In addition, the pad P_{ADD1} is connected to the external terminal T11 with wire bonding. Further, the circuit F12 generates an AND signal of three signals at the pads P15, P16 and P_{ADD1} as the signal CNT1.

When the first modification technique is applied to the configuration of FIG. 17, the pad P_{ADD1} is connected to an end of a not-shown pull-up resistor, and the other end of the pull-up resistor is applied with the power supply voltage VDD1. In addition, the pad P_{ADD1} is connected to the external terminal T12 or T16 with wire bonding. Further, the circuit F12 generates an OR signal of three signals at the pads P15, P16 and P_{ADD1} as the signal CNT1.

The same is true for the chip 20. In other words, for example, in the chip 20, a second modification technique is considered in which a pad P_{ADD2} (not shown) as a third control pad is added to the pads P26 and P25 as the first and second control pads.

When the second modification technique is applied to the configuration of FIG. 14, the pad P_{ADD2} is not connected to any one of the external terminals, the pad P_{ADD2} is connected to an end of a not-shown pull-down resistor, and the other end of the pull-down resistor is applied with the ground voltage GND2. Further, the circuit F22 generates an OR signal of three signals at the pads P26, P25 and P_{ADD2} as the signal CNT2.

When the second modification technique is applied to the configuration of FIG. 15, the pad P_{ADD2} is not connected to any one of the external terminals, the pad P_{ADD2} is connected to an end of a not-shown pull-up resistor, and the other end of the pull-up resistor is applied with the power supply voltage VDD2. Further, the circuit F22 generates an AND signal of three signals at the pads P26, P25 and P_{ADD2} as the signal CNT2.

When the second modification technique is applied to the configuration of FIG. 16, the pad P_{ADD2} is connected to an end of a not-shown pull-up resistor, and the other end of the pull-up resistor is applied with the power supply voltage VDD2. In addition, the pad P_{ADD2} is connected to the external terminal T21 with wire bonding. Further, the circuit F22 generates an AND signal of three signals at the pads P26, P25 and P_{ADD2} as the signal CNT2.

When the second modification technique is applied to the configuration of FIG. 17, the pad P_{ADD2} is connected to an end of a not-shown pull-up resistor, and the other end of the pull-up resistor is applied with the power supply voltage VDD2. In addition, the pad P_{ADD2} is connected to the external terminal T22 or T26 with wire bonding. Further, the circuit F22 generates an OR signal of three signals at the pads P26, P25 and P_{ADD2} as the signal CNT2.

### [Example EX1_7]

Example EX1_7 is described below. The signals EN1 and EN2 are each an enable signal as an example of the external control signal. The enable signal instructs to perform or not to perform an operation of the functional circuit. Therefore, if the external control signal is the signals EN1 and EN2, performing or not performing of the operation of the functional circuit F11 is controlled by the signal CNT1 based on the signal EN1, and performing or not performing of the operation of the functional circuit F21 is controlled by the signal CNT2 based on the signal EN2.

However, as a modification, for example, the external control signal may be an initial level specification signal. When the semiconductor device 1 is activated, the signals OUTB and OUTA have a predetermined initial level. The initial level is either one of low level and high level.

If the external control signal is the initial level specification signal, a first initial level specification signal is input to the external terminal T15 from the processing device 2. Alternatively, the level of the first initial level specification signal may be fixed to low level or high level by a not-shown pull-down resistor or pull-up resistor disposed outside of the semiconductor device 1. The first initial level specification signal of high level is a signal that instructs to set the initial level of the signal OUTB to high level, while the first initial level specification signal of low level is a signal that instructs to set the initial level of the signal OUTB to low level. Therefore, if the first initial level specification signal of high level is input to the external terminal T15, the signal CNT1 of high level is generated by the circuit F12 on the basis of the first initial level specification signal of high level, and the functional circuit F11 receives the signal CNT1 of high level so as to set the initial level of the signal OUTB to high level. On the contrary, if the first initial level specification signal of low level is input to the external terminal T15, the signal CNT1 of low level is generated by the circuit F12 on the basis of the first initial level specification signal of low level, and the functional circuit F11 receives the signal CNT1 of low level so as to set the initial level of the signal OUTB to low level.

Similarly, if the external control signal is the initial level specification signal, a second initial level specification signal is input to the external terminal T25 from the processing device 3. Alternatively, the level of the second initial level specification signal may be fixed to low level or high level by a not-shown pull-down resistor or pull-up resistor disposed outside of the semiconductor device 1. The second initial level specification signal of high level is a signal that instructs to set the initial level of the signal OUTA to high level, while the second initial level specification signal of low level is a signal that instructs to set the initial level of the signal OUTA to low level. Therefore, if the second initial level specification signal of high level is input to the external terminal T25, the signal CNT2 of high level is generated by the circuit F22 on the basis of the second initial level specification signal of high level, and the functional circuit F21 receives the signal CNT2 of high level so as to set the initial level of the signal OUTA to high level. On the contrary, if the second initial level specification signal of low level is input to the external terminal T25, the signal CNT2 of low level is generated by the circuit F22 on the basis of the second initial level specification signal of low level, and the functional circuit F21 receives the signal CNT2 of low level so as to set the initial level of the signal OUTA to low level.

Other than that, the external control signal may be an arbitrary control signal for controlling an operation of the functional circuit.

### Second Embodiment

A second embodiment of the present disclosure is described below. The semiconductor device 1 (see FIG. 1) described above in the first embodiment transmits one digital signal in an insulated form from the circuit block CB1 to the circuit block CB2 and transmits another digital signal in an insulated form from the circuit block CB2 to the circuit block CB1. However, the semiconductor device 1 may transmit two or more digital signals in an insulated form from the circuit block CB1 to the circuit block CB2 or may transmit two or more digital signals in an insulated form from the circuit block CB2 to the circuit block CB1.

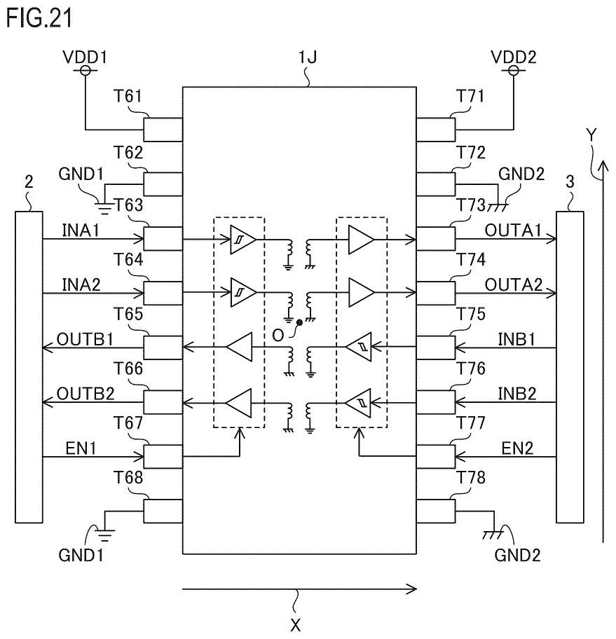

For instance, it may be possible to constitute a semiconductor device 1J illustrated in FIG. 21, and to apply the technique described in the first embodiment to the semiconductor device 1J. In the system SYS of FIG. 1, an applied technology is used in which the signal INA is constituted of the two digital signals INA1 and INA2, the signal OUTB is constituted of the two digital signals OUTB1 and OUTB2, the signal INB is constituted of the two digital signals INB1 and INB2, and the signal OUTA is constituted of the two digital signals OUTA1 and OUTA2, and with this applied technology, the semiconductor device 1 is transformed into the semiconductor device 1J.

A case of the semiconductor device 1J has a first side and a second side facing each other. The first side and the second side are parallel to the Y-axis. The first side and the second side correspond to the sides SD1 and SD2 in FIG. 4. In the case of the semiconductor device 1J, external terminals T61 to T68 are disposed on the first side, and external terminals T71 to T78 are disposed on the second side. On the first side, the external terminals T61 to T68 are arranged in this order from the positive side to the negative side of the Y-axis. On the second side, the external terminals T71 to T78 are arranged in this order from the positive side to the negative side of the Y-axis. The origin O is positioned at the center or substantially the center of the case of the semiconductor device 1J. Note that as described above, the X-axis and the Y-axis cross each other at the origin O in reality as illustrated in FIG. 4, but in FIG. 21, for convenience sake of illustration, the X-axis and the Y-axis are shown shifted from the origin O.

The external terminal T61 is a power supply terminal that receives the power supply voltage VDD1. The external terminals T62 and T68 are ground terminals connected to the ground GND1 (and hence receive the ground voltage GND1). The external terminals T63 and T64 are input terminals that respectively receive the signals INA1 and INA2 from the processing device 2. The external terminals T65 and T66 are output terminal that respectively output the signals OUTB1 and OUTB2 from the semiconductor device 1J to the processing device 2. The external terminal T67 is a control terminal that receives the signal EN1 from the processing device 2.

The external terminal T71 is a power supply terminal that receives the power supply voltage VDD2. The external terminals T72 and T78 are ground terminals connected to the ground GND2 (and hence receive the ground voltage GND2). The external terminals T73 and T74 are output terminals that respectively output the signals OUTA1 and OUTA2 from the semiconductor device IJ to the processing device 3. The external terminals T75 and T76 are input terminals that respectively receive the signals INB1 and INB2 from the processing device 3. The external terminal T77 is a control terminal that receives the signal EN2 from the processing device 3.

When the signals EN1 and EN2 are both in asserted state, the semiconductor device 1J realizes bidirectional communication between the processing devices 2 and 3. In other words, when the signals EN1 and EN2 are both in asserted state, the semiconductor device 1J performs the first transmission of transmitting the signals INA1 and INA2 supplied from the processing device 2 to the processing device 3 as the signals OUTA1 and OUTA2, respectively, and the second transmission of transmitting the signals INB1 and INB2 supplied from the processing device 3 to the processing device 2 as the signals OUTB1 and OUTB2, respectively. These transmissions are performed in an insulated form using an insulation element (a pulse transformer or a capacitor) disposed in the semiconductor device 1J. If the signal EN1 in negated state, the second transmission is not performed, and if the signal EN2 is in negated state, the first transmission is not performed. Alternatively, if at least one of the signals EN1 and EN2 is in negated state, both the first transmission and the second transmission are not performed.

Arrangement positions of the external terminals T61 and T71 have a line-symmetric relationship. Similarly, arrangement positions of the external terminals T62 and T72, arrangement positions of the external terminals T63 and T73, arrangement positions of the external terminals T64 and T74, arrangement positions of the external terminals T65 and T75, arrangement positions of the external terminals T66 and T76, arrangement positions of the external terminals T67 and T77, and arrangement positions of the external terminals T68 and T78, each have a line-symmetric relationship. On the XY plane, the symmetry axes of these line-symmetric relationships are the axis that is parallel to the first side and the second side and is positioned at the center between the first side and the second side, which may correspond to the Y-axis illustrated in FIG. 4.

The semiconductor device 1 of FIG. 7 and the semiconductor device 1J of FIG. 21 have a symmetric structure in an arrangement of the external terminals, and the semiconductor device 1 and the semiconductor device 1J have the same symmetric structure.

In other words, in the semiconductor device 1 of FIG. 7, when the arrangement position of the input terminal (T13) on the circuit block CB1 side is rotated by 180 degrees about the axis that passes the origin O and is orthogonal to the XY plane as the rotation axis, the position after the rotation is the arrangement position of the input terminal (T24) on the circuit block CB2 side. In addition, in the semiconductor device 1 of FIG. 7, when the arrangement position of the output terminal (T14) on the circuit block CB1 side is rotated by 180 degrees about the axis that passes the origin O and is orthogonal to the XY plane as the rotation axis, the position after the rotation is the arrangement position of the output terminal (T23) on the circuit block CB2 side. In other words, in the semiconductor device 1 of FIG. 7, the arrangement position of the input terminal (T13) on the circuit block CB1 side and the arrangement position of the input terminal (T24) on the circuit block CB2 side have a point-symmetric relationship, with respect to the origin O, and the arrangement position of the output terminal (T14) on the circuit block CB1 side and the arrangement position of the output terminal (T23) on the circuit block CB2 side have a point-symmetric relationship, with respect to the origin O. In each of these point symmetries, the point of symmetry is the origin O.

Similarly to the above symmetric structure (the structure related to the point symmetry) of the semiconductor device 1 of FIG. 7, in the semiconductor device 1J of FIG. 21, when the arrangement position of the input terminal (T63, T64) on the circuit block CB1 side is rotated by 180 degrees about the axis that passes the origin O and is orthogonal to the XY plane as the rotation axis, the position after the rotation is the arrangement position of the input terminal (T76, T75) on the circuit block CB2 side. In addition, in the semiconductor device 1J of FIG. 21, when the arrangement position of the output terminal (T65, T66) on the circuit block CB1 side is rotated by 180 degrees about the axis that passes the origin O and is orthogonal to the XY plane as the rotation axis, the position after the rotation is the arrangement position of the output terminal (T74, T73) on the circuit block CB2 side. In other words, in the semiconductor device 1J of FIG. 21, the arrangement position of the input terminal (T63, T64) on the circuit block CB1 side and the arrangement position of the input terminal (T76, T75) on the circuit block CB2 side have a point-symmetric relationship, with respect to the origin O, and the arrangement position of the output terminal (T65, T66) on the circuit block CB1 side and the arrangement position of the output terminal (T74, T73) on the circuit block CB2 side have a point-symmetric relationship, with respect to the origin O. In each of these point symmetries, the point of symmetry is the origin O.

In addition, in the semiconductor device 1 of FIG. 7, among external terminals other than the input terminals (T13, T24) and the output terminals (T14, T23), external terminals having corresponding functions have arrangement positions having a line-symmetric relationship between the circuit blocks CB1 and CB2. In other words, in the semiconductor device 1 of FIG. 7, the arrangement position of the power supply terminal (T11) on the circuit block CB1 side and the arrangement position of the power supply terminal (T24) on the circuit block CB2 side have a line-symmetric relationship, the arrangement position of the ground terminal (T12, T16) on the circuit block CB1 side and the arrangement position of the ground terminal (T22, T26) on the circuit block CB2 side have a line-symmetric relationship, and the arrangement position of the control terminal (T15) on the circuit block CB1 side and the arrangement position of the control terminal (T25) on the circuit block CB2 side have a line-symmetric relationship. On the XY plane, each of the symmetry axes of these line-symmetric relationships is the axis that is parallel to the sides SD1 and SD2 and is positioned at the center between the sides SD1 and SD2, which may correspond to the Y-axis illustrated in FIG. 4.

Similarly to the above symmetric structure (the structure related to the line-symmetric) of the semiconductor device 1 of FIG. 7, in the semiconductor device 1J of FIG. 21, among external terminals other than the input terminals (T63, T64, T75, T76) and the output terminals (T65, T66, T73, T74), external terminals having corresponding functions have arrangement positions having a line-symmetric relationship between the circuit blocks CB1 and CB2. In other words, in the semiconductor device IJ of FIG. 21, the arrangement position of the power supply terminal (T61) on the circuit block CB1 side and the arrangement position of power supply terminal (T71) on the circuit block CB2 side have a line-symmetric relationship, and the arrangement position of the ground terminal (T62, T68) on the circuit block CB1 side and the arrangement position of the ground terminal (T72, T78) on the circuit block CB2 side have a line-symmetric relationship, and the arrangement position of the control terminal (T67) on the circuit block CB1 side and the arrangement position of the control terminal (T77) on the circuit block CB2 side have a line-symmetric relationship. On the XY plane, the symmetry axes of these line-symmetric relationships are the axis that is parallel to the first side and the second side and is positioned at the center between the first side and the second side, which may correspond to the Y-axis illustrated in FIG. 4.

The technique of the present disclosure can be widely applied to semiconductor devices having the above symmetric structure of the arrangement of external terminals, and the semiconductor device according to the present disclosure is not limited to a digital isolator.

Note that for an arbitrary signal or voltage, a relationship between high level and low level can be opposite to that described above, in a form without impairing the spirit described above.

The embodiment of the present disclosure can be appropriately modified variously within the scope of the technical concept recited in the claims. The above embodiment is merely an example of the embodiment of the present disclosure, and meanings of terms in the present disclosure and of the structural elements are not limited to those described in the above embodiment. The specific numeric values shown in the above description are merely examples, and they can be changed to various values as a matter of course.

### Additional Notes

Additional notes are given below for the present disclosure in which specific structural examples are shown in the above embodiment.

The semiconductor device according to one aspect of the present disclosure is a semiconductor device (1) including a first chip (10) and a second chip (20), having a configuration (first configuration), in which each chip including a high-side pad (P11, P28) configured to be applied with a high-side voltage, a low-side pad (P12, P27) configured to be applied with a low-side voltage lower than the high-side voltage, two or more control pads (P15, P16, P26, P25), an input pad (P13, P23) configured to be applied with an input signal to the semiconductor device, an output pad (P14, P24) configured to be applied with an output signal to outside of the semiconductor device, and a functional circuit (F11, F21) that is a circuit connected to the input pad and the output pad, and is configured to operate on the basis of the high-side voltage and the low-side voltage. In each chip, the two or more control pads are each pulled down to the low-side voltage or pulled up to the high-side voltage, and in each chip, the two or more control pads include a target control pad (P15, P26) configured to receive an external control signal from outside of the semiconductor device, and in each chip, an internal control signal (CNT1, CNT2) is generated on the basis of two or more signals applied to the two or more control pads, and an operation of the functional circuit is controlled on the basis of the internal control signal.

In this way, a desired operation in a functional circuit can be secured while commonalization of the chips can be achieved.

The semiconductor device according to the first configuration (1A; see FIG. 14) may have a configuration (second configuration), in which in each chip, the two or more control pads are each pulled down to the low-side voltage, and an OR signal of the two or more signals applied to the two or more control pads is generated as the internal control signal.

The semiconductor device according to the first configuration (1B; see FIG. 15) may have a configuration (third configuration), in which in each chip, the two or more control pads are each pulled up to the high-side voltage, and an AND signal of the two or more signals applied to the two or more control pads is generated as the internal control signal.

The semiconductor device according to the third configuration (1B′; see FIG. 16) may have a configuration (fourth configuration), in which in each chip, out of the two or more control pads, a control pad different from the target control pad is a non-target control pad (P16, P25), and in each chip, the high-side pad and the non-target control pad are commonly connected to a terminal (T11, T21) applied with the high-side voltage.

In this way, fast startup and a desired operation in a functional circuit can be secured while commonalization of the chips can be achieved.

The semiconductor device according to the fourth configuration (1B′; see FIG. 16) may have a configuration (fifth configuration), in which a case (CS) that houses the first chip and the second chip, and a plurality of external terminals exposed from the case are disposed, the plurality of external terminals include a first power supply terminal (T11) configured to receive a first power supply voltage (VDD1) and a second power supply terminal (T21) configured to receive a second power supply voltage (VDD2), the high-side pad (P11) in the first chip and the non-target control pad (P16) in the first chip are commonly connected to the first power supply terminal using wire bonding, so as to receive the first power supply voltage as the high-side voltage of the first chip, and the high-side pad (P28) in the second chip and the non-target control pad (P25) in the second chip are commonly connected to the second power supply terminal using wire bonding, so as to receive the second power supply voltage as the high-side voltage of the second chip.

The semiconductor device according to the first configuration (1C; see FIG. 17) may have a configuration (sixth configuration), in which in each chip, the two or more control pads are each pulled up to the high-side voltage, and an OR signal of the two or more signals applied to the two or more control pads is generated as the internal control signal, in each chip, out of the two or more control pads, a control pad different from the target control pad is a non-target control pad (P16, P25), and in each chip, the low-side pad and the non-target control pad are commonly connected to a terminal (T12, T22) applied with the low-side voltage.

In this way, fast startup and a desired operation in a functional circuit can be secured while commonalization of the chips can be achieved.

The semiconductor device according to the sixth configuration may have a configuration (seventh configuration), in which a case (CS) that houses the first chip and the second chip, and a plurality of external terminals exposed from the case are disposed, the plurality of external terminals include a first ground terminal (T12) configured to receive a first ground voltage (GND1) and a second ground terminal (T22) configured to receive a second ground voltage (GND2), the low-side pad (P12) in the first chip and the non-target control pad (P16) in the first chip are commonly connected to the first ground terminal (T12) using wire bonding, so as to receive the first ground voltage as the low-side voltage of the first chip, and the low-side pad (P27) in the second chip and the non-target control pad (P25) in the second chip are commonly connected to the second ground terminal (T22) using wire bonding, so as to receive the second ground voltage as the low-side voltage of the second chip.

The semiconductor device according to any one of the first to seventh configurations may have a configuration (eighth configuration), in which two chips having the same structure are used as the first chip and the second chip.

The semiconductor device according to the eighth configuration may have a configuration (ninth configuration), in which the high-side pad, the low-side pad, the two or more control pads, the input pad and the output pad are disposed on a principal surface of each chip, and the first chip and the second chip are disposed in such a manner that the first chip and the second chip have a point-symmetric relationship, with respect to a point between the first chip and the second chip, on a two-dimensional plane parallel to the principal surface of each chip.

The semiconductor device according to any one of the first to fourth, sixth and eighth configurations, the semiconductor device may have a configuration (tenth configuration), in which the semiconductor device includes a case (CS) that houses the first chip and the second chip, and a plurality of external terminals exposed from the case, two chips having the same structure are used as the first chip and the second chip, the high-side pad, the low-side pad, the two or more control pads, the input pad and the output pad are disposed on a principal surface of each chip, the first chip and the second chip are disposed in such a manner that the first chip and the second chip have a point-symmetric relationship, with respect to a point between the first chip and the second chip, on a two-dimensional plane parallel to the principal surface of each chip, the plurality of external terminals include a first external terminal group arranged on a first side (SD1) of the case, and a second external terminal group arranged on a second side (SD2) of the case, the first side and the second side facing each other, the first external terminal group include a first power supply terminal (T11) configured to receive a first power supply voltage (VDD1) that functions as the high-side voltage of the first chip, a first ground terminal (T12) configured to receive a first ground voltage (GND1) that functions as the low-side voltage of the first chip, a first input terminal (T13) configured to receive the input signal to the input pad of the first chip, a first output terminal (T14) configured to receive the output signal from the output pad of the first chip, and a first control terminal (T15) configured to receive the external control signal to the target control pad of the first chip, the second external terminal group include a second power supply terminal (T21) configured to receive a second power supply voltage (VDD2) that functions as the high-side voltage of the second chip, a second ground terminal (T22) configured to receive a second ground voltage (GND2) that functions as the low-side voltage of the second chip, a second output terminal (T23) configured to receive the output signal from the output pad of the second chip, a second input terminal (T24) configured to receive the input signal to the input pad of the second chip, and a second control terminal (T25) configured to receive the external control signal to the target control pad of the second chip, the first power supply terminal, the first ground terminal, the first input terminal, the first output terminal, and the first control terminal are respectively connected to the high-side pad, the low-side pad, the input pad, the output pad, and the target control pad in the first chip with wire bonding, and the second power supply terminal, the second ground terminal, the second output terminal, the second input terminal, and the second control terminal are respectively connected to the high-side pad, the low-side pad, the output pad, the input pad, and the target control pad in the second chip with wire bonding.

The semiconductor device according to any one of the first to tenth configurations may have a configuration (eleventh configuration), in which in each chip, performing or not performing of the operation of the functional circuit is controlled on the basis of the internal control signal.

The semiconductor device according to any one of the first to eleventh configurations may have a configuration (twelfth configuration), in which bidirectional communication is performed using the functional circuit in the first chip and the functional circuit in the second chip, and in the bidirectional communication, the input signal to the input pad of the first chip is transmitted to the output pad of the second chip, so as to generate the output signal at the output pad of the second chip, while the input signal to the input pad of the second chip is transmitted to the output pad of the first chip, so as to generate the output signal at the output pad of the first chip.

The semiconductor device according to the twelfth configuration may have a configuration (thirteenth configuration), in which the first chip and the second chip are insulated from each other, and the bidirectional communication is performed using an insulation element (31, 32).

1. A semiconductor device comprising a first chip and a second chip, wherein each chip includes a high-side pad configured to be applied with a high-side voltage, a low-side pad configured to be applied with a low-side voltage lower than the high-side voltage, two or more control pads, an input pad configured to be applied with an input signal to the semiconductor device, an output pad configured to be applied with an output signal to outside of the semiconductor device, and a functional circuit that is a circuit connected to the input pad and the output pad, and is configured to operate on the basis of the high-side voltage and the low-side voltage,
in each chip, the two or more control pads are each pulled down to the low-side voltage or pulled up to the high-side voltage,
in each chip, the two or more control pads include a target control pad configured to receive an external control signal from outside of the semiconductor device, and
in each chip, an internal control signal is generated on the basis of two or more signals applied to the two or more control pads, and an operation of the functional circuit is controlled on the basis of the internal control signal.

2. The semiconductor device according to claim 1, wherein in each chip, the two or more control pads are each pulled down to the low-side voltage, and an OR signal of the two or more signals applied to the two or more control pads is generated as the internal control signal.

3. The semiconductor device according to claim 1, wherein in each chip, the two or more control pads are each pulled up to the high-side voltage, and an AND signal of the two or more signals applied to the two or more control pads is generated as the internal control signal.

4. The semiconductor device according to claim 3, wherein
in each chip, out of the two or more control pads, a control pad different from the target control pad is a non-target control pad, and
in each chip, the high-side pad and the non-target control pad are commonly connected to a terminal applied with the high-side voltage.

5. The semiconductor device according to claim 4, wherein
the semiconductor device includes a case that houses the first chip and the second chip, and a plurality of external terminals exposed from the case,
the plurality of external terminals include a first power supply terminal configured to receive a first power supply voltage and a second power supply terminal configured to receive a second power supply voltage,
the high-side pad in the first chip and the non-target control pad in the first chip are commonly connected to the first power supply terminal using wire bonding, so as to receive the first power supply voltage as the high-side voltage of the first chip, and
the high-side pad in the second chip and the non-target control pad in the second chip are commonly connected to the second power supply terminal using wire bonding, so as to receive the second power supply voltage as the high-side voltage of the second chip.

6. The semiconductor device according to claim 1, wherein in each chip, the two or more control pads are each pulled up to the high-side voltage, and an OR signal of the two or more signals applied to the two or more control pads is generated as the internal control signal,
in each chip, out of the two or more control pads, a control pad different from the target control pad is a non-target control pad, and
in each chip, the low-side pad and the non-target control pad are commonly connected to a terminal applied with the low-side voltage.

7. The semiconductor device according to claim 6, wherein
the semiconductor device includes a case that houses the first chip and the second chip, and a plurality of external terminals exposed from the case,
the plurality of external terminals include a first ground terminal configured to receive a first ground voltage and a second ground terminal configured to receive a second ground voltage,
the low-side pad in the first chip and the non-target control pad in the first chip are commonly connected to the first ground terminal using wire bonding, so as to receive the first ground voltage as the low-side voltage of the first chip, and
the low-side pad in the second chip and the non-target control pad in the second chip are commonly connected to the second ground terminal using wire bonding, so as to receive the second ground voltage as the low-side voltage of the second chip.

8. The semiconductor device according to claim 1, wherein two chips having the same structure are used as the first chip and the second chip.

9. The semiconductor device according to claim 8, wherein the high-side pad, the low-side pad, the two or more control pads, the input pad and the output pad are disposed on a principal surface of each chip, and
the first chip and the second chip are disposed in such a manner that the first chip and the second chip have a point-symmetric relationship, with respect to a point between the first chip and the second chip, on a two-dimensional plane parallel to the principal surface of each chip.

10. The semiconductor device according to claim 1, wherein
the semiconductor device includes a case that houses the first chip and the second chip, and a plurality of external terminals exposed from the case,
two chips having the same structure are used as the first chip and the second chip, the high-side pad, the low-side pad, the two or more control pads, the input pad and the output pad are disposed on a principal surface of each chip,
the first chip and the second chip are disposed in such a manner that the first chip and the second chip have a point-symmetric relationship, with respect to a point between the first chip and the second chip, on a two-dimensional plane parallel to the principal surface of each chip,
the plurality of external terminals include a first external terminal group arranged on a first side of the case, and a second external terminal group arranged on a second side of the case, the first side and the second side facing each other,
the first external terminal group include a first power supply terminal configured to receive a first power supply voltage that functions as the high-side voltage of the first chip, a first ground terminal configured to receive a first ground voltage that functions as the low-side voltage of the first chip, a first input terminal configured to receive the input signal to the input pad of the first chip, a first output terminal configured to receive the output signal from the output pad of the first chip, and a first control terminal configured to receive the external control signal to the target control pad of the first chip,
the second external terminal group include a second power supply terminal configured to receive a second power supply voltage that functions as the high-side voltage of the second chip, a second ground terminal configured to receive a second ground voltage that functions as the low-side voltage of the second chip, a second output terminal configured to receive the output signal from the output pad of the second chip, a second input terminal configured to receive the input signal to the input pad of the second chip, and a second control terminal configured to receive the external control signal to the target control pad of the second chip,
the first power supply terminal, the first ground terminal, the first input terminal, the first output terminal, and the first control terminal are respectively connected to the high-side pad, the low-side pad, the input pad, the output pad, and the target control pad in the first chip with wire bonding, and
the second power supply terminal, the second ground terminal, the second output terminal, the second input terminal, and the second control terminal are respectively connected to the high-side pad, the low-side pad, the output pad, the input pad, and the target control pad in the second chip with wire bonding.

11. The semiconductor device according to claim 1, wherein in each chip, performing or not performing of the operation of the functional circuit is controlled on the basis of the internal control signal.

12. The semiconductor device according to claim 1, wherein
bidirectional communication is performed using the functional circuit in the first chip and the functional circuit in the second chip, and
in the bidirectional communication, the input signal to the input pad of the first chip is transmitted to the output pad of the second chip, so as to generate the output signal at the output pad of the second chip, while the input signal to the input pad of the second chip is transmitted to the output pad of the first chip, so as to generate the output signal at the output pad of the first chip.

12. The semiconductor device according to claim 12, wherein
the first chip and the second chip are insulated from each other, and
the bidirectional communication is performed using an insulation element.
